(19) United States
(12) Patent Application Publication
(10) Pub. No.: US 2008/0048164 A1
(43) Pub. Date: Feb. 28, 2008

(54) ELECTRO-RESISTANCE ELEMENT, METHOD OF MANUFACTURING THE SAME AND ELECTRO-RESISTANCE MEMORY USING THE SAME

(75) Inventor: Akihiro ODAGAWA, Osaka (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., OSAKA (JP)

(21) Appl. No.: 11/774,101

(22) Filed: Jul. 6, 2007

(30) Foreign Application Priority Data
Jul. 11, 2006 (JP) 2006-190862

(51) Int. Cl. H01L 29/02; H01L 21/00

(52) U.S. Cl. 257/2; 438/104; 257/E29.002; 257/E21.001

(57) ABSTRACT

An electro-resistance element that develops less leakage and fewer associated short-circuits even when an electro-resistance layer is made thinner, a method of manufacturing the same and an electro-resistance memory using the same are provided. The electro-resistance element includes a first electrode, a second electrode, an electro-resistance layer stacked between the first and the second electrodes and an insulating layer (a tunnel barrier layer). The tunnel barrier layer has a thickness in a range from 0.5 nm to 5 nm both inclusive. The electro-resistance layer is a layer having a plurality of states in which electric resistance values are different and being switchable between the states by applying a voltage or a current between the first and the second electrodes. The electro-resistance layer contains transition metal oxide as its main component.

### BACKGROUND OF THE INVENTION

1. Field of the Invention

The present invention relates to an electro-resistance element, a method of manufacturing the same and an electro-resistance memory using the same.

2. Related Background Art

In recent years, demands for miniaturization of memory elements have been increasing. Accordingly, electro-resistance memory elements (non-volatile memory elements) that record information by changes in electric resistance, not by changes in charge capacity, have attracted attention as a memory element that is less prone to the adverse effects of miniaturization.

Electro-resistance memory elements include an electro-resistance layer and two electrodes disposed to sandwich the layer. This element can be in a plurality of states in which the electric resistances are different, and the state can be changed by applying a predetermined voltage or current between the electrodes. The one selected state basically is maintained as long as a predetermined operation is not performed (i.e., it is non-volatile). Such an effect is known as Colossal Electro-Resistance: CER. CER effect is distinguished from Magneto-Resistance: MR, which shows change in resistance as well, by the differences in operation mechanisms and problems.

MR effect is observed in a multilayer structure in which magnetic materials sandwich a non-magnetic material, i.e., a multilayer structure of magnetic material/non-magnetic material/magnetic material. When the magnetization direction of one of the magnetic materials in the multilayer structure is changed by the magnetic field, the resistance is changed based on the difference of the magnetization direction, i.e., whether the direction is parallel or antiparallel to that of the other magnetic material. Such an effect is the MR effect. Magnetic materials increase their demagnetizing field component when miniaturized. Thus, elements employing an MR effect have a disadvantage that the magnetic field required to reverse the magnetization is enlarged with the miniaturization (densification).

Since CER effect does not have such a disadvantage in size and it exhibits much larger change in resistance compared to the MR effect, an electro-resistance memory element is expected highly as the next generation non-volatile memory to which miniaturization is required.

As an electro-resistance memory element, U.S. Pat. No. 6,204,139 discloses an element employing a perovskite oxide (Pr_{0.7}Ca_{0.3}MnO₃:PCMO) and JP 2002-537627A discloses elements employing various oxides including a perovskite oxide (BaSrTiCrO₃:BSTCO). These elements are known as electro-resistance random access memories (Resistance RAM), and they draw attention. In particular, these non-volatile memory elements that record information by changes in electric resistance value are expected highly for superintegration, since they have fewer restrictions on size.

In order to manufacture a minute electro-resistance memory element by a simple and stable method, the electro-resistance layer has to be thin. However, when electro-resistance layers become thinner than a certain value, they are subject to easy deterioration such as leakage and associated short-circuit, and integration of elements becomes difficult. Thus, there have been tradeoffs between making an electro-resistance layer thinner and reducing leakage. For further pursuing more integration, it is necessary to achieve a memory element developing less leakage even when the electro-resistance layer is made thinner.

### SUMMARY OF THE INVENTION

Giving consideration on such circumstances, it is an object of the present invention to provide an electro-resistance element that develops less leakage and fewer associated short-circuits even when the electro-resistance layer is made thinner, a method of manufacturing the same and an electro-resistance memory using the same.

In order to solve the above-mentioned problems, an electro-resistance element according to the present invention includes a first electrode, a second electrode, and an electro-resistance layer and an insulating layer stacked between the first and the second electrodes. The insulating layer has a thickness in a range from 0.5 nm to 5 nm both inclusive. The electro-resistance layer is a layer having a plurality of states in which electric resistance values are different and being switchable between the states by applying a voltage or a current between the first and the second electrodes. The electro-resistance layer contains transition metal oxide as its main component.

An electro-resistance memory of the present invention includes the electro-resistance element of the present invention as a memory element.

A method for manufacturing an electro-resistance element of the present invention is a method of manufacturing an electro-resistance element includes an electro-resistance layer having a plurality of states in which electric resistance values are different and being switchable between the states by applying a voltage or a current. The manufacturing method includes (i) forming a first electrode, (ii) forming a stacked structure including an insulating layer and the electro-resistance layer on the first electrode and (iii) forming a second electrode on the stacked structure. The insulating layer has a thickness in a range from 0.5 nm to 5 nm both inclusive. The electro-resistance layer contains transition metal oxide as its main component.

According to the present invention, an electro-resistance element that develops less leakage and fewer associated short-circuits even when the electro-resistance layer is made thinner is obtained. Use of such electro-resistance elements enables a highly integrated electro-resistance memory to be obtained.

Since the electro-resistance element of the present invention includes an insulating layer functioning as a tunnel barrier, current can be reduced when the status of the electro-resistance layer is changed. Thus, the element of the present invention consumes less power while driving and is particularly suitable for higher integration.

### BRIEF DESCRIPTION OF THE DRAWINGS

FIG. 1 is a cross-sectional view schematically illustrating an example of the electro-resistance element according to the present invention.

FIG. 2 is a cross-sectional view schematically illustrating another example of the electro-resistance element according to the present invention.

FIGS. 3A and 3B are charts illustrating an example of characteristics of the electro-resistance element according to the present invention.

FIG. 4 is a chart illustrating another example of characteristics of the electro-resistance element according to the present invention.

FIG. 5 is a connection diagram schematically illustrating an example of the configuration of the electro-resistance memory of the present invention.

FIG. 6 is a cross-sectional view schematically illustrating an example of the electro-resistance memory of the present invention.

FIG. 7 is a chart for illustrating an example of the information recording and reading method in the electro-resistance memory of the present invention.

FIG. 8 is a chart for illustrating another example of the information recording and reading method in the electro-resistance memory of the present invention.

FIG. 9 is a chart for illustrating an example of the information reading method in the electro-resistance memory of the present invention.

FIG. 10 is a schematic view illustrating an example of the electro-resistance memory (memory array) of the present invention.

FIG. 11 is a schematic view illustrating another example of the electro-resistance memory (memory array) of the present invention.

FIG. 12 is a schematic view illustrating still another example of the electro-resistance memory (memory array) of the present invention.

FIGS. 13A to 13G are process drawings schematically illustrating an example of the method of manufacturing an electro-resistance element according to the present invention.

FIGS. 14A to 14H are process drawings schematically illustrating another example of the method of manufacturing an electro-resistance element according to the present invention.

FIG. 15 is a plan view schematically illustrating an example of the electro-resistance element according to the present invention.

FIG. 16 is a cross-sectional view taken along the line XVI-XVI of FIG. 15.

### DETAILED DESCRIPTION OF THE INVENTION

Hereinbelow, embodiments of the present invention are described. The present invention is not limited to the description of the embodiments and the examples below. Although some parts of the description are illustrated with specific numeric values and materials, other values and materials may be applied as long as the effects of the present invention can be obtained.

### [Electro-Resistance Element]

An electro-resistance element of the present invention includes a first electrode, a second electrode, and an electro-resistance layer and an insulating layer (hereinafter, also referred to as “a tunnel barrier layer”) stacked between the first and the second electrodes. A multilayer structure including a first electrode, a second electrode, an electro-resistance layer and an insulating layer (a tunnel barrier layer) is formed generally on a substrate. From another perspective, the electro-resistance element of the present invention includes a substrate and the multilayer structure formed on the substrate. The electro-resistance element of the present invention may have adjacent layers stacked at least in a part of each layer.

The tunnel barrier layer is a layer in which a tunnel current flows. The tunnel barrier layer generally has a thickness in a range from 0.5 nm to 5 nm both inclusive and, for example, from 0.7 nm to 2 nm both inclusive. This tunnel barrier layer enables the reduction of power consumption while driving. Specific examples of material for the tunnel barrier layer are described later. The tunnel barrier layer is made of insulating material. Although the tunnel barrier layer may have a part with a thickness in a range wider than that defined above depending on the shape of the layer, the part of the layer making contact with the electrodes preferably has the thickness within the defined range.

The electro-resistance layer is a layer having a plurality of states in which electric resistance values are different and being switchable between the states by applying a voltage or a current between the first and the second electrodes. The electro-resistance layer contains transition metal oxide as its main component. Specifically, a transition metal oxide content in the electro-resistance layer is equal to or more than 50 weight %, and is generally equal to or more than 80 weight %. A typical example of the electro-resistance layer is made of transition metal oxide.

The tunnel barrier layer (the insulating layer) may be disposed between the electro-resistance layer and the first electrode or between the electro-resistance layer and the second electrode. The tunnel barrier layer disposed between the electro-resistance layer and the first electrode or between the electro-resistance layer and the second electrode enables reducing leakage and associated short-circuits developed when the status of electro-resistance layer is changed. In addition, current can be reduced when the status of the electro-resistance layer is changed.

Still in addition, the electro-resistance element of the present invention may include two tunnel barrier layers in total, one between the electro-resistance layer and the first electrode, and the other between the electro-resistance layer and the second electrode.

In the electro-resistance element of the present invention, the electro-resistance layer may have a thickness in a range from 1 nm to 500 nm both inclusive. The thickness of the electro-resistance layer also may be more than 5 nm, equal to or more than 10 nm, or equal to or more than 30 nm. The thickness of the electro-resistance layer may be equal to or less than 100 nm, or equal to or less than 50 nm, as well. For example, the thickness of the electro-resistance layer may be in a range from 30 nm to 50 nm both inclusive.

In the electro-resistance element of the present invention, the transition metal oxide may be iron oxide. Employing the electro-resistance layer made of iron oxide enables easy development of resistance change characteristic, and it particularly gives advantages in characteristics such as a high speed operation by pulse application in the order of nanoseconds. Specific examples of transition metal oxide are described later.

Although the junction area in the electro-resistance element of the present invention is not particularly limited, it may be equal to or less than 0.25 μm², for example. Here, “junction area” means the smaller area of the overlapping areas between the electro-resistance layer and the first or the second electrode.

In the electro-resistance element of the present invention, a voltage or a current applied between the electrodes to change the state of the electro-resistance layer may be in a pulse form. A voltage or a current also may be applied in forms other than pulse as long as it can change the state of the layer.

### [Electro-Resistance Memory]

An electro-resistance memory of the present invention includes the electro-resistance element of the present invention as a memory element.

The electro-resistance memory of the present invention may include a plurality of the electro-resistance elements arranged in a matrix. A typical example of the memory of the present invention includes a substrate and a plurality of the electro-resistance elements of the present invention aligned in a matrix on the substrate.

In addition, the electro-resistance memory of the present invention further may include a switching element connected to the electro-resistance element.

### [Method of Manufacturing an Electro-Resistance Element]

The method of the present invention is a method of manufacturing an electro resistance element including an electro-resistance layer having a plurality of states in which electric resistance values are different and being switchable between the states by applying a voltage or a current. According to this manufacturing method, the electro-resistance element of the present invention can be obtained. Since materials and thicknesses of components of the electro-resistance element are the same as those of the electro-resistance element of the present invention, repetitive description may be omitted. This manufacturing method includes the following steps from (i) to (iii).

In the step (i), a first electrode is formed. The first electrode may be formed directly on a substrate, or it may be formed indirectly on a substrate having a certain structure (e.g. a layer) in between.

Next, in the step (ii), a stacked structure including an insulating layer (a tunnel barrier layer) and the electro-resistance layer is formed on the first electrode. The tunnel barrier layer has a thickness in a range from 0.5 nm to 5 nm both inclusive. The electro-resistance layer contains transition metal oxide as its main component. Either one of the tunnel barrier layer and the electro-resistance layer may be formed in advance of the other. For example, the stacked structure may include the tunnel barrier layer (the insulating layer) formed on the first electrode and the electro-resistance layer formed on the tunnel barrier layer. In addition, the stacked structure may include the electro-resistance layer formed on the first electrode and the tunnel barrier layer (the insulating layer) formed on the electro-resistance layer.

Then, in the step (iii), a second electrode is formed on the stacked structure. The manufacturing method of the present invention can form an element having a structure of a first electrode/a tunnel barrier layer/an electro-resistance layer/a second electrode or a structure of a first electrode/an electro-resistance layer/a tunnel barrier layer/a second electrode. Methods of manufacturing the first and the second electrodes, the tunnel barrier layer and the electro-resistance layer are not particularly limited, and they may be formed by known methods.

According to the manufacturing method of the present invention, in the step (ii), the tunnel barrier layer may be formed by repeating a film forming step and an oxidizing step a plurality of times, where the film forming step forms a precursor film including an element constituting the tunnel barrier layer and the oxidizing step oxidizes the precursor film under an oxidizing atmosphere. A tunnel barrier layer made of aluminum oxide, for example, may be formed by forming an aluminum film as a precursor film and oxidizing the aluminum film.

In addition, in the oxidizing step, a plurality of substrates having the precursor film formed thereon may be oxidized all at one time under the oxidizing atmosphere.

Still in addition, the oxidizing atmosphere may be any atmosphere selected from oxygen gas atmosphere, oxygen plasma atmosphere and ozone atmosphere.

Hereinbelow, the present invention is described specifically with reference to the drawings. In the following description, the same components are denoted by the same reference numerals, and the repetitive description may be omitted.

### [An Example of the Electro-Resistance Element]

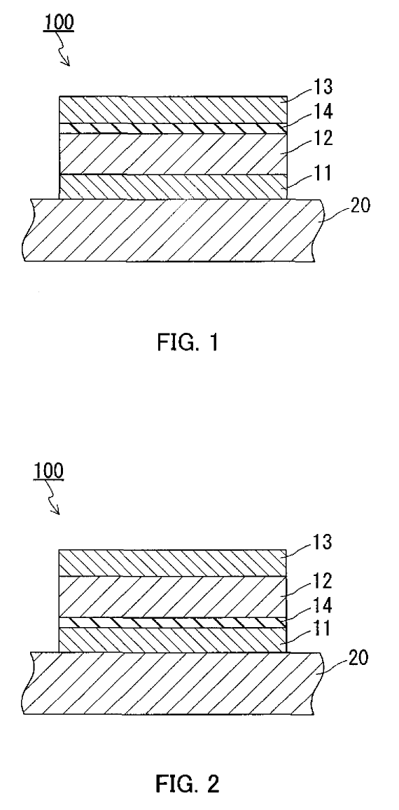

FIG. 1 shows a cross-sectional view of an example of the electro-resistance element according to the present invention. An electro-resistance element 100 in FIG. 1 is formed on a substrate 20. The electro-resistance element 100 includes a lower electrode (a first electrode) 11, an electro-resistance layer 12, an upper electrode (a second electrode) 13 and a tunnel barrier layer 14.

The electro-resistance element 100 is a multilayer structure including the lower electrode 11 an electro-resistance layer 12, a tunnel barrier layer 14 and an upper electrode 13 that are stacked in this order from the substrate 20. The tunnel barrier layer 14 is an insulator. The electro-resistance layer 12 is composed of transition metal oxide.

The structure of the electro-resistance element of the present invention is not particularly limited as long as the electro-resistance layer 12 and the tunnel barrier layer 14 are disposed between the lower electrode 11 and the upper electrode 13. For example, the tunnel barrier layer 14 may be disposed between the electro-resistance layer 12 and the upper electrode 13 as shown in FIG. 1, and it also may be disposed between the lower electrode 11 and the electro-resistance layer 12 as shown in FIG. 2.

The electro-resistance element 100 has equal to or more than two states in which electric resistance values are different. From the states equal to or more than two, the element 100 is switched from one selected state to another by applying a predetermined voltage or current to the element 100. For example, the element 100 has a state of relatively high resistance (hereinafter, also referred to as “a high resistance state”) and a state of relatively low resistance (hereinafter, also referred to as “a low resistance state”). The element 100 is changed from the high resistance state to the low resistance state, or from the low resistance state to high resistance state by applying a predetermined voltage or current.

The electro-resistance element of the present invention has excellent resistance change characteristics, such as resistance change ratio. The resistance change ratio is a numerical value indicating a resistance change characteristic of an element. Specifically, it is a value obtained by the following formula where R_{MAX} denotes the maximum electric resistance value and R_{MIN} denotes the minimum electric resistance value that an element shows.

[Resistance Change Ratio]=(R_{MAX}−R_{MIN})/R_{MIN}

The tunnel barrier layer 14 is formed from insulating material. The tunnel barrier layer 14 preferably is formed from aluminum oxide (Al₂O₃), silicon oxide (SiO₂), magnesium oxide (MgO), titanium oxide (TiO₂), titanium aluminum oxynitride (TiAlON), tantalum oxide (TaO₂), tantalum aluminum oxynitride (TaAlON), silicon nitride (SiN) and silicon oxynitride (SiON), for example. When employing the tunnel barrier layer 14 as thin as 0.5 nm, the preferred material is aluminum oxide (Al₂O₃). The tunnel barrier layer 14 may be formed from insulating material other than transition metal oxide, such as an oxide of a metal element other than transition metal element.

A preferred example of material for the electro-resistance layer 12 is oxide of iron (Fe), i.e., iron oxide. Since iron oxide is an abundantly available resource, it costs less and is suitable for mass production. Examples of iron oxide are oxides represented by the chemical formulas Fe₂O₃ and Fe₃O₄. Electro-resistance elements employing iron oxide have advantages in characteristics, such as easy development of resistance change characteristic and a high speed operation particularly by pulse application in the order of nanoseconds. Although the reason for exhibiting such characteristics is not yet clearly determined, one possible explanation is that the exhibition is derived from the diversity of iron oxide, such as the capability of iron ions in iron oxide for having various valence numbers and the sensitive changeability in characteristic depending on oxygen distribution and slight changes in oxygen content. Other examples of the material for the electro-resistance layer are WO₃, ferrite material having the spinel structure such as MFe₂O₄ (M denotes a transition metal element, and its examples may be Co, Mn, Ni, Zn and Cu), material with the corundum structure such as α-Fe₂O₃ and Ti₂O₃, material with the rutile structure (including Magneli phase) such as MnO₂, WO₂ and TiO₂, for example. It should be noted that “transition metal” in this specification includes Zn.

The lower electrode 11 basically may have conductivity. The lower electrode 11 can be formed from materials such as gold (Au), platinum (Pt), ruthenium (Ru), iridium (Ir), titanium (Ti), aluminum (Al), copper (Cu), tantalum (Ta), iridium-tantalum alloy (Ir—Ta) or indium-tin oxide (ITO), or any alloy, oxide, nitride, fluoride, carbide, boride or silicide of these.

From a perspective of semiconductor manufacturing processes, the lower electrode 11 preferably is formed from materials such as iridium (Ir), ruthenium (Ru), iridium oxide (Ir—O), ruthenium oxide (Ru—O), titanium (Ti), aluminum (Al), Ti—Al alloy or nitride of these. The lower electrode 11 also preferably employs a stacked structure, for example that of iridium oxide and Ti—Al—N (titanium aluminum nitride). To maintain conductivity in this case, (TiAl) alloy ratio, i.e., ratio of Al amount in the total amount of (Ti+Al), is preferably equal to or less than 50 atom %.

The upper electrode 13 basically may have conductivity. The upper electrode 13 can be formed from materials such as gold (Au), platinum (Pt), ruthenium (Ru), iridium (Ir), titanium (Ti), aluminum (Al), copper (Cu), tantalum (Ta), iridium-tantalum alloy (Ir—Ta) or indium-tin oxide (ITO), or any alloy, oxide, nitride, fluoride, carbide, boride or silicide of these.

From a perspective of semiconductor manufacturing processes, the upper electrode 13 preferably employs metal as its material, capable of maintaining conductivity after oxidization. Thus, the upper electrode 13 preferably has a material such as iridium (Ir), ruthenium (Ru), rhenium (Re), osmium (Os), rhodium (Rh), platinum (Pt) and gold (Au). The upper electrode 13 also preferably is formed by using oxide such as Ir—O (iridium oxide), Ru—C (ruthenium oxide), Re—O (rhenium oxide), Os—O (osmium oxide) and Rh—O (rhodium oxide), alloy nitride such as Ti—Al—N (titanium aluminum nitride) or a stacked structure of these. To maintain conductivity in this case, (TiAl) alloy ratio is preferably equal to or less than 50%.

Both of the two electrodes in the electro-resistance element of the present invention also may be formed of non-magnetic material.

The substrate 20 may employ a semiconductor substrate (such as a silicon substrate), for example. In the case of employing a semiconductor substrate, the electro-resistance element of the present invention and semiconductive element easily can be formed on an identical substrate. A surface of the substrate 20 making contact with the lower electrode 11 may be oxidized. Similarly, an oxide film may be formed on a surface of the substrate 20. The substrate 20 includes substrates having transistors or contact plugs formed thereon as well as simple semiconductor substrates.

The tunnel barrier layer 14 has a thickness in a range from 0.5 nm to 5 nm. The electro-resistance layer 12 preferably has a thickness in a range from 1 nm to 500 nm. A preferable example of the element of the present invention has the tunnel barrier layer 14 with a thickness in a range from 0.5 nm to 2 nm and the electro-resistance layer 12 with a thickness in a range from 30 nm to 50 nm. In this example, the tunnel barrier layer 14 may be made of alumina and the electro-resistance layer 12 may be made of iron oxide.

The predetermined voltage or current (driving voltage or current) is applied to the electro-resistance element 100 via the lower electrode 11 and the upper electrode 13. The application of the predetermined voltage or current changes the state of the element 100 from the high resistance state into the low resistance state, for example. The state after the change (the low resistance state, for example) is retained until the predetermined voltage or current is applied to the element 100 again. Another application of the predetermined voltage or current can change the state of the element 100 again (from the low resistance state into the high resistance state, for example).

The predetermined voltages or currents applied to the element 100 for changing its state are not necessarily identical between when the element 100 is in the high resistance state and when in the low resistance state, and the magnitude and application direction may vary depending on the state of the element 100. That is, “a predetermined voltage or current” in the present specification may be such a “voltage or current” that can change the element 100 in a certain state into another state that is different from the former state.

Thus, the element 100 retains a specific state showing a specific electric resistance value until a predetermined voltage or current is applied to the element 100. Accordingly, a non-volatile electro-resistance memory can be constructed by combining the element 100 with a mechanism for detecting the states of the element 100 (i.e., a mechanism for measuring the electric resistance value of the element 100). This memory assigns a bit to each state of the element 100 described above. For example, it assigns “0” to the high resistance state and “1” to the low resistance state. The electro-resistance memory may be a memory element or a memory array in which a plurality of memory elements are aligned. Since such a state change of the element 100 can be repeated at least twice, a stable non-volatile random access memory can be obtained. The element 100 also can be applied as a switching element by assigning ON or OFF to each state described above.

The voltage or the current to be applied to the element 100 is preferably in a pulse form. Employment of a voltage or a current in a pulse form enables reducing power consumption and improving switching efficiency in an electronic device (such as a memory) composed of the element 100. The pulse shape is not particularly limited and may be at least one selected from a sine waveform, a rectangular waveform and a triangular waveform, for example. The pulse width may be generally in a range from some nanoseconds to some milliseconds.

For easier driving of the electronic devices, the pulse shape is preferably in a triangular waveform. To make the response of the element 100 faster (as fast as in a range from some nanoseconds to some microseconds, for example), the pulse shape is preferably in a rectangular waveform.

In order to achieve the easier driving, the power consumption reduction and the faster response speed, the pulse is preferably in a sine waveform or in a trapezoidal waveform formed by replacing the rising and falling edges of the rectangular waveform with suitably sloped shapes. The pulses of the sine and trapezoidal waveforms are suitable for the response speed of the element 100 defined in a range from some tens of nanoseconds to some hundreds of microseconds, while the triangular waveform pulse is suitable for the response speed of the element 100 defined in a range from some tens of microseconds to some milliseconds.

When a voltage application changes the state of the element 100, miniaturization of the element 100 and size reduction of the devices including the element 100 becomes easier. For example, the state of the element 100 can be changed by connecting the element 100 to a voltage application device that generates a potential difference between the lower electrode 11 and the upper electrode 13 of the element 100 for a voltage application between the electrodes. Two methods of changing the state of the element 100 by a voltage application are described below.

In the first method, the element 100 may be changed from the low resistance state to the high resistance state by applying a bias voltage that makes the potential of the lower electrode 11 positive compared to that of the upper electrode 13 (a positive bias voltage) between both of the electrodes, while the state of the element 100 may be changed from the high resistance state to the low resistance state by applying a bias voltage that makes the potential of the lower electrode 11 negative compared to that of the upper electrode 13 (a negative bias voltage) between both of the electrodes. In this method, the direction of voltage application (polarity) on changing from the high resistance state to the low resistance state is opposite from that on changing from the low resistance state to the high resistance state. Hereinafter, the voltage that makes the potential of the lower electrode 11 positive compared to that of the upper electrode 13 also is referred to as “a positive bias voltage”, and the voltage that makes the potential of the lower electrode 11 negative compared to that of the upper electrode 13 also is referred to as “a negative bias voltage”.

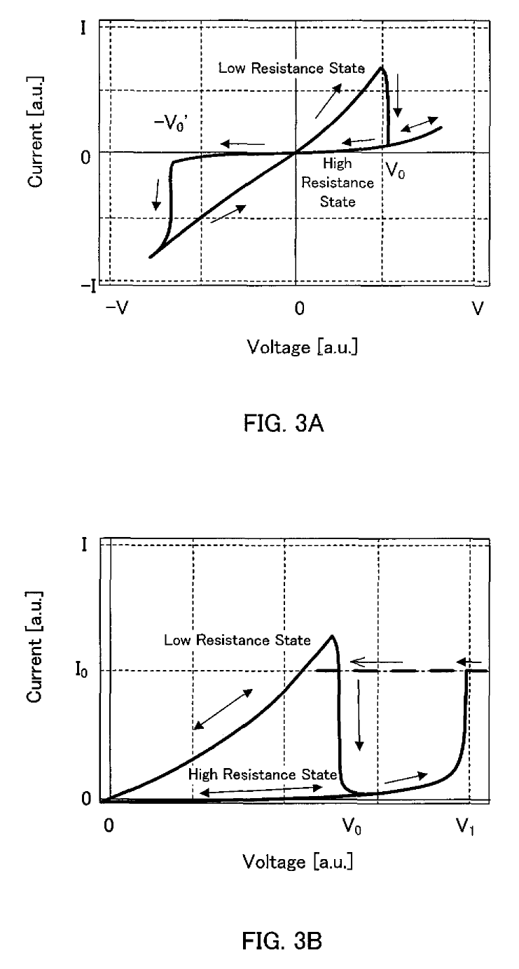

The first method is described further with an example of the element 100 having a current-voltage (I-V) characteristic as shown in FIG. 3A. In the first method, as shown in FIG. 3A, the I-V characteristic changes in the order indicated by the arrows along with the voltage application. Specifically, application of a positive bias voltage V₀ changes the element 100 from the low resistance state to the high resistance state, and application of a negative bias voltage −V₀′ changes the element 100 from the high resistance state to the low resistance state.

In contrast, in the second method, the element 100 is changed from the low resistance state to the high resistance state by applying a positive bias voltage V₀ to the element 100, and the element 100 is changed from the high resistance state to the low resistance state by applying a positive bias voltage V₁ that is larger than V₀ to the element 100. The second method changes the element 100 from the high resistance state to the low resistance state by applying a voltage larger than that for changing from the low resistance state to the high resistance state. The second method also can make the same status change by applying a negative bias voltage.

The second method is described further with an example of the element 100 having a I-V characteristic as shown in FIG. 3B. In the second method, as shown in FIG. 3B, application of a positive bias voltage V₀ changes the element 100 from the low resistance state to the high resistance state, and application of a positive bias voltage V₁ changes from the high resistance state to the low resistance state. To prevent the element from malfunctioning by too much current, a compliance (I=I₀) preferably is determined at a certain current when changing the element from the high resistance state to the low resistance state. Although this paragraph described the example of applying positive bias voltages, application of a negative bias voltage can establish the same operation.

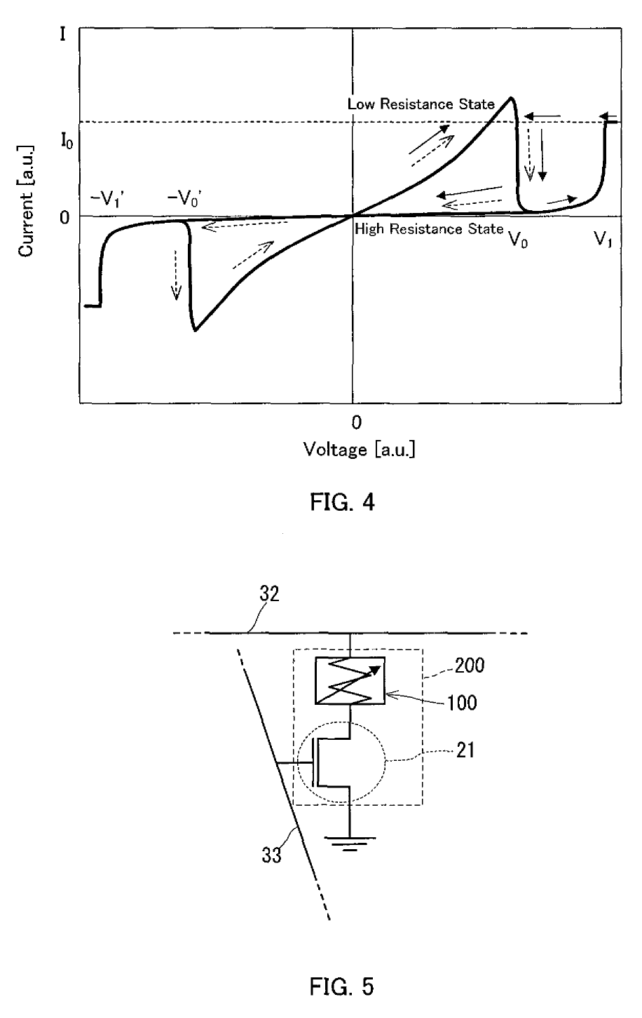

In order to achieve operation of the first and the second methods, the element 100 may exhibit a I-V characteristic as shown in FIG. 4. The operation becomes possible by changing the applying bias voltage and the application method. The broken line arrows in FIG. 4 indicate control by the bias voltage direction. The solid line arrows in FIG. 4 indicate control by the bias voltage magnitude.

### [An Example of the Electro-Resistance Memory]

FIG. 5 shows a connection diagram of an example of the electro-resistance memory (element) of the present invention, which is composed of an electro-resistance element of the present invention and a MOS field effect transistor (MOS-FET).

An electro-resistance memory element 200 shown in FIG. 5 includes an electro-resistance element 100 and a transistor 21. The electro-resistance element 100 is connected electrically to an electrode of the transistor 21 and a bit line 32. A gate electrode of the transistor 21 is connected electrically to a word line 33. The other electrode of the transistor 21 is grounded. Such memory element 200 enables detection of the states in the element 100 (i.e., detection of the electric resistance value of the element 100) and application of a predetermined voltage or current to the element 100, using the transistor 21 as a switching element. For example, the memory element 200 shown in FIG. 5 may be used as a 1-bit electro-resistance memory element when the element 100 shows two states in which the electric resistance values are different.

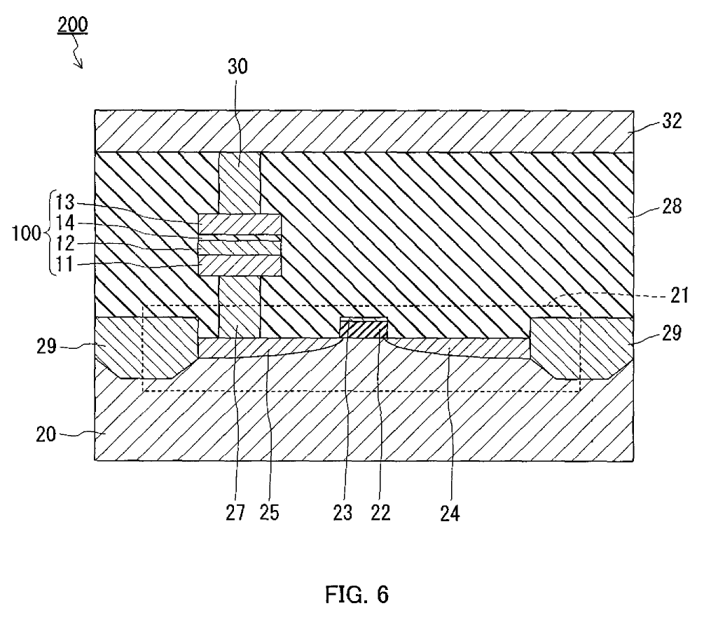

FIG. 6 shows a cross-sectional view of an example of a specific configuration of the electro-resistance memory (element) of the present invention. In the memory element 200 shown in FIG. 6, the transistor 21 and the electro-resistance element 100 are formed on a silicon substrate (the substrate 20), and the transistor 21 and the element 100 are integrated. The transistor 21 may have a common configuration as a MOS-FET.

The configuration of the memory element 200 in FIG. 6 is illustrated specifically. A source electrode 24 and a drain electrode 25 are formed on the substrate 20. The drain electrode 25 is connected to the lower electrode 11 via a plug 27. The source electrode 24 is connected to a grounding potential and the like through an electrode, for example. Element isolating sections 29 are formed on a surface of the substrate 20. A gate electrode 23 is formed via a gate insulating film 22 on a surface between the source electrode 24 and the drain electrode 25 on the substrate 12. The electro-resistance layer 12, the tunnel barrier layer 14 and the upper electrode 13 are disposed on the lower electrode 11 in this order. The gate electrode 23 is connected electrically to a word line (not shown). The upper electrode 13 is connected to the bit line 32 via a plug 30. An interlayer insulating layer 28 is disposed on the substrate 20 covering all over the surface of the substrate 20, each electrode and the element 100. The interlayer insulating layer 28 prevents electric leakage from developing between each electrode.

The interlayer insulating layer 28 may be formed from insulating material, and the material also may have a stacked structure made of two or more of materials. The insulating material may be inorganic material such as SiO₂ or Al₂O₃, or may be an organic material such as a resist material. Employing an organic material enables an easy formation of the interlayer insulating layer 28 having a planar surface by using a technique such as spinner coating even when it has to be formed on a non-planar surface. An example of preferred organic material is a material such as polyimide, which is a photosensitive resin.

Although an electro-resistance memory is composed by combining an electro-resistance element with a MOS-FET in the example shown in FIG. 6, the configuration of the electro-resistance memory of the present invention is not particularly limited. It also may be combined, for example, with an arbitrary semiconductor element, such as other types of transistors or diodes.

Although the memory element 200 shown in FIG. 6 has the electro-resistance element 100 disposed directly on the transistor 21, the transistor 21 may be disposed at distant locations from the element 100 and the lower electrode 11 and the drain electrode 25 may be connected electrically by an extraction electrode. For easier processes of manufacturing the memory element 200, the electro-resistance element 100 and the transistor 21 preferably are disposed apart from each other. On the other hand, since the area occupied by the memory element 200 becomes smaller when the element 100 is disposed directly on the transistor 21, it is possible to realize an electro-resistance memory array with a higher density as shown in FIG. 6.

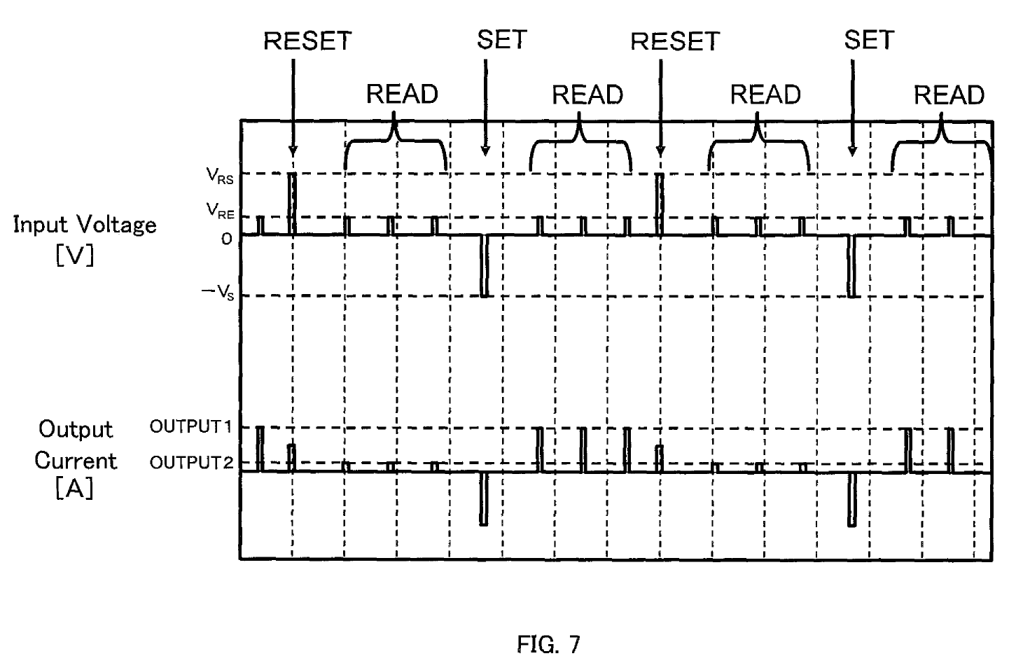

Information may be recorded into the memory element 200 by applying a predetermined voltage or current to the element 100, and the information recorded in the element 100 may be read by, for example, applying a voltage or a current altered in magnitude from that when recorded to the element 100. An example of a method for applying a voltage in a pulse form to the element 100 as a method of recording and reading information is illustrated with reference to FIG. 7.

In the example shown in FIG. 7, the electro-resistance element 100 is changed from the low resistance state into the high resistance state by applying a positive bias voltage having a magnitude equal to or more than a certain threshold value (V₀), and it is changed from the high resistance state into the low resistance state by applying a negative bias voltage having a magnitude equal to or more than a certain threshold value (|V₀′|) (refer to FIG. 3A). The magnitude of each bias voltage corresponds to the magnitude of the potential difference between the lower electrode 11 and the upper electrode 13.

Suppose the initial state of the element 100 is in the low resistance state. The element 100 is changed from the low resistance state into the high resistance state when applying a positive bias voltage in a pulse form V_{RS} (|V_{RS}|≧V₀) between the lower electrode 11 and the upper electrode 13 (RESET shown in FIG. 7). The positive bias voltage applied here is denoted as a reset voltage (RESET voltage).

At this point, the electric resistance value of the element 100 can be obtained from a current output of the element 100 by applying a positive bias voltage with a magnitude of less than V₀ to the element 100. The electric resistance value also can be detected by applying a negative bias voltage with a magnitude of less than V₀′ to the element 100. These voltages applied for detecting the electric resistance value of the element 100 are denoted as a read voltage (READ voltage: V_{RE}). The read voltage may be in a pulse form as shown in FIG. 7. Employing the read voltage in a pulse form enables reduction in power consumption and improvement in switching efficiency in the memory element 200 similar to the case of the reset voltage in a pulse form. Since the application of the read voltage does not change the state of the element 100, an identical electric resistance value can be detected even when applying the read voltage a plurality of times.

Subsequently, the element 100 is changed from the high resistance state into the low resistance state when a set voltage V_{S} (|V_{S}|≧|V₀′|), which is a negative bias voltage in a pulse form, is applied between the lower electrode 11 and the upper electrode 13 (SET shown in FIG. 7). The electric resistance value of the element 100 can be obtained from the current output of the element 100 (OUTPUT1 shown in FIG. 7) by applying the read voltage to the element 100.

In such a way, information can be recorded and read to and from the memory element 200 by applying a voltage in a pulse form. The magnitude of the output current from the element 100 upon reading varies corresponding to the state of the element 100. When the state of the output current being relatively small (OUTPUT2 in FIG. 7) is defined as “1” and that of relatively large (OUTPUT1 in FIG. 7) is defined as “0”, the memory element 200 can be a memory element that records the information “1” by the reset voltage and records the information “0” (erases the information “1”) by the set voltage.

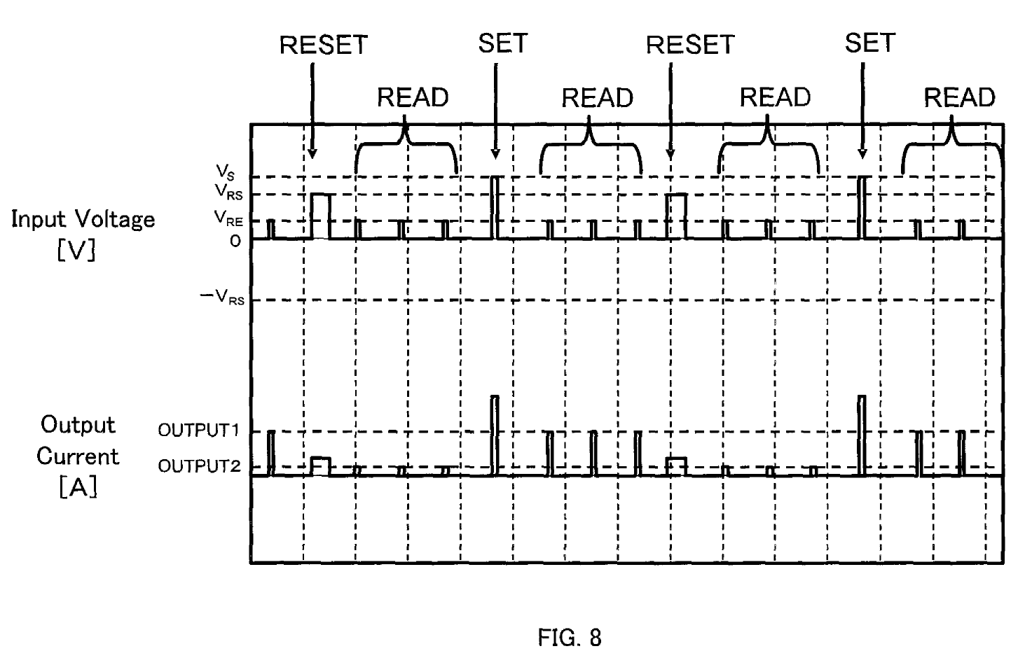

In addition, another operational embodiment is illustrated with reference to FIG. 8. Application of a positive bias voltage having a magnitude equal to or more than certain threshold value (V₀) changes the electro-resistance element 100 used in the embodiment of FIG. 8 from the low resistance state to the high resistance state, and application of a positive bias voltage having a magnitude equal to or more than certain threshold value (V₁) changes it from the high resistance state to the low resistance state (refer to FIG. 3B). In this type of embodiment, application of a negative bias voltage also can change the status of the element in the same way.

Suppose the initial state of the element 100 is in the low resistance state. The element 100 is changed from the low resistance state to the high resistance state when applying a reset voltage V_{RS} (|V_{RS}|≧V₀), which is a positive bias voltage in a pulsed form, between the lower electrode 11 and the upper electrode 13 (RESET shown in FIG. 8). At this point, the electric resistance value of the element 100 can be obtained from a current output of the element 100 (OUTPUT2 in FIG. 8) by applying a read voltage (V_{RE}), which is a positive bias voltage with a magnitude of less than V₀, to the element 100. The read voltage may be in a pulse form as shown in FIG. 8.

Subsequently, the element 100 is changed from the high resistance state to the low resistance state when a set voltage V_{S} (|V_{S}|≧V₁), which is a positive bias voltage in a pulse form, is applied between the lower electrode 11 and the upper electrode 13 (SET shown in FIG. 8). The electric resistance value of the element 100 can be obtained from the current output of the element 100 (OUTPUT1 shown in FIG. 8) by applying the read voltage to the element 100.

In such a way, information can be recorded and read to and from the memory element 200 by applying a voltage in a pulse form. The magnitude of the output current from the element 100 obtained by reading varies corresponding to the state of the element 100. When the state of the output current being relatively small (OUTPUT2 in FIG. 8) is defined as “1” and that of relatively large (OUTPUT1 in FIG. 8) is defined as “0”, the memory element 200 can be a memory element that records the information “1” by the reset voltage and records the information “0” (erases the information “1”) by the set voltage.

To apply a voltage in a pulse form to the element 100 in the memory element 200 shown in FIG. 6, the transistor 21 may be turned ON by the word line; a voltage may be applied via the bit line 32.

The magnitude of the read voltage is preferably in a range from ¼ to 1/1000 of that of the set and the reset voltages, in general. Specific values of the set and the reset voltages are normally in the range from 0.1 V to 20 V, preferably in the range from 1 V to 12 V, while they are dependent on the configuration of the element 100.

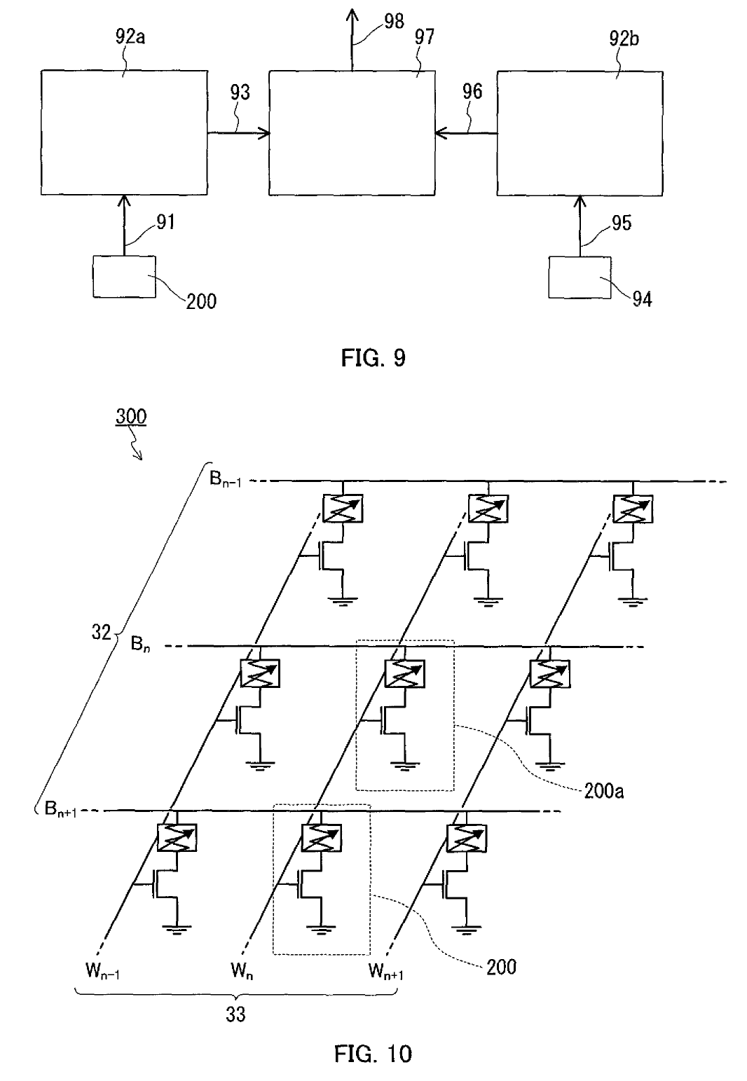

The electric resistance value of the element 100 preferably is calculated based on a difference between a resistance value (or an output current value) of the element 100 and a reference resistance value (or a reference output current value) of a reference element. The reference resistance value of the reference element can be obtained by applying the read voltage to a reference element, which is prepared separately from the element 100, in the same manner as to the element 100. FIG. 9 shows an example of a circuit configuration for measuring by such method.

The method shown in FIG. 9 inputs an output 93 obtained by amplifying an output 91 from the memory element 200 by a negative feedback amplification circuit 92a and an output 96 obtained by amplifying an output 95 from a reference element 94 by a negative feedback amplification circuit 92b into a differential amplification circuit 97. The element resistance is thus obtained by using an output signal 98 obtained from the differential amplification circuit 97.

Alignment of two or more memory elements 200 in a matrix enables constructing a non-volatile random access electro-resistance memory (memory array) 300, as shown in FIG. 10. The memory 300 can record and read information to and from a memory element 200a, which is located at a coordinate (Bₙ, Wₙ), by selecting a bit line (Bₙ) from two or more bit lines 32 and a word line (Wₙ) from two or more word lines 33. As shown in FIG. 10, at least one memory element 200 may be a reference element when two or more memory elements 200 are aligned in a matrix.

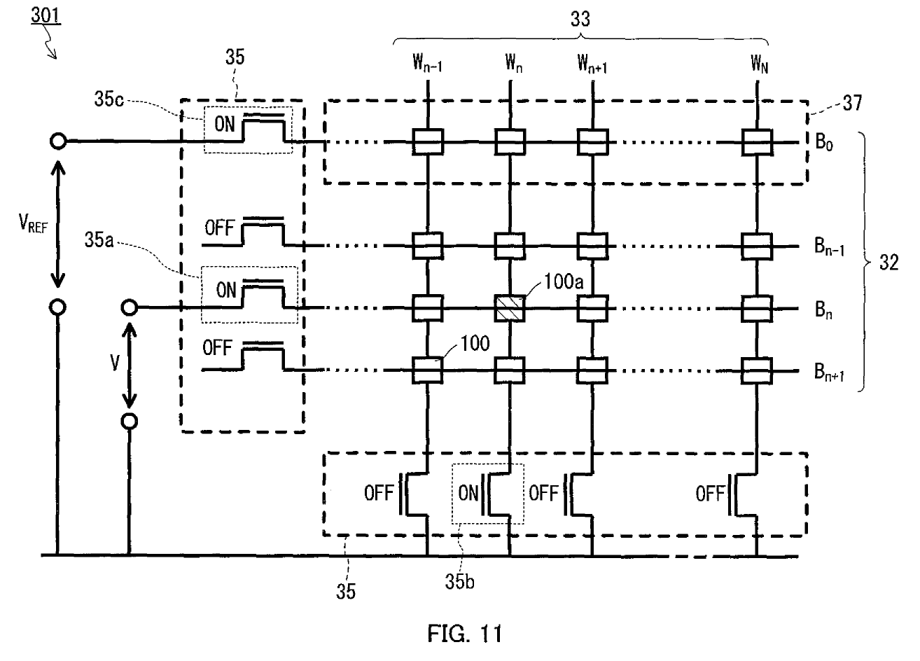

Alignment of two or more electro-resistance elements 100 in a matrix using pass transistors 35 also enables constructing a non-volatile random access electro-resistance memory (memory array) 301, as shown in FIG. 11. In the memory 301, the bit lines 32 are connected to the lower electrodes 11 of the elements 100, and the word lines 33 to the upper electrodes 13 of the elements 100, respectively. The memory 301 enables recording and reading information to and from an electro-resistance element 100a located at a coordinate (Bₙ, Wₙ) by selectively turning ON a pass transistor 35a that is connected to a bit line (Bₙ) selected from the two or more bit lines 32 and a pass transistor 35b that is connected to a word line (Wₙ) selected from the two or more word lines 33. Information may be read by, for example, measuring the voltage V shown in FIG. 11, which is the voltage corresponding to the electric resistance value of the element 100a.

A reference element group 37 is disposed in the memory 301 shown in FIG. 11. The difference between the outputs from the element 100a and from the group 37 can be detected by selectively turning ON a pass transistor 35c corresponding to a bit line (B₀) connected to the group 37 and by measuring the voltage V_{REF} shown in FIG. 11.

In addition, an array shown in FIG. 11, in which each element is connected to each other via an unselected element, can read by newly preparing resistance components via unselected elements as a reference element group and by measuring the difference output similarly. This method facilitates the configuration of the memory, although the operation becomes slower due to the necessity of assigning a resistance value to the reference elements while referring to the memory state of each element in the arrays on the vicinity of the selected elements.

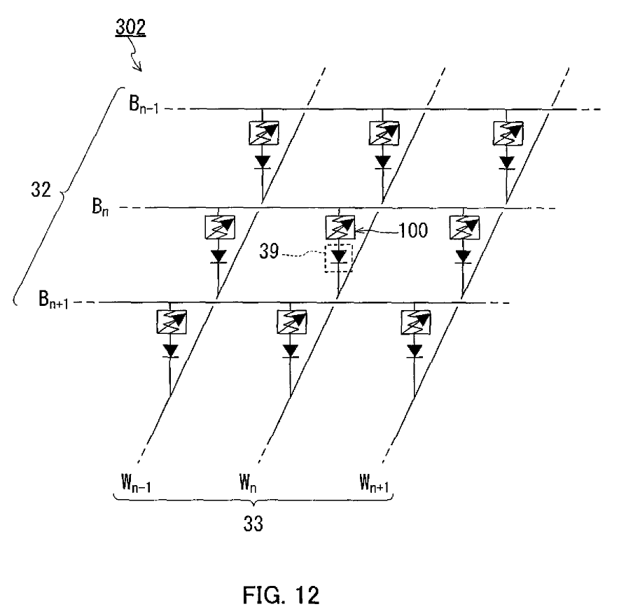

Still in addition, a serial connection of elements having a nonlinear current-voltage characteristic (diodes, for example) to each electro-resistance element can reduce the resistance components of unselected element, as shown in FIG. 12. FIG. 12 shows a memory 302 having diodes 39 connected to electro-resistance elements 100 in serial.

### [Examples of Method of Manufacturing an Electro-Resistance Element]

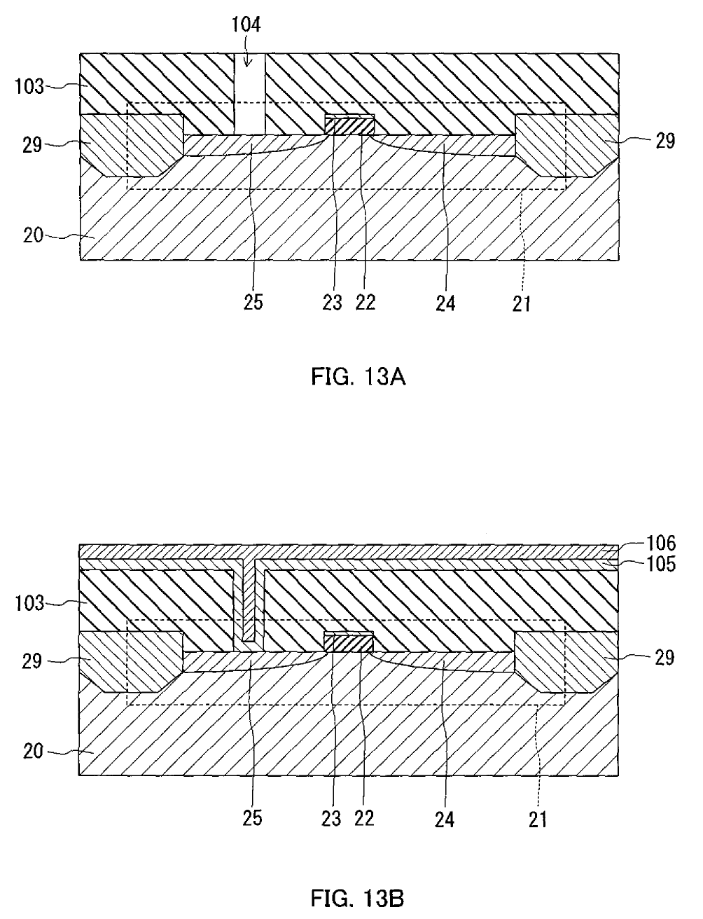

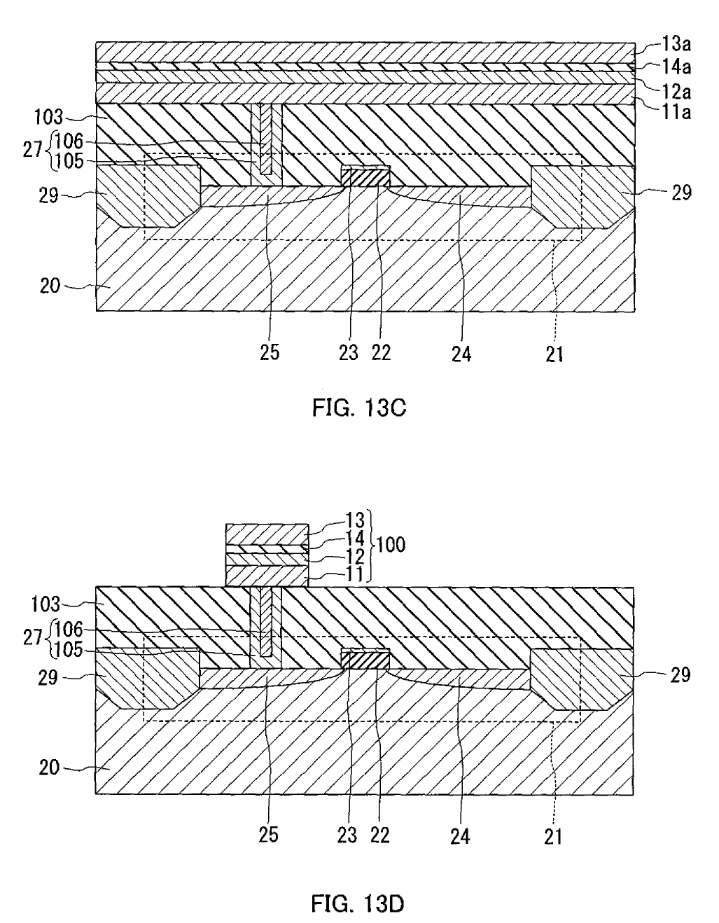

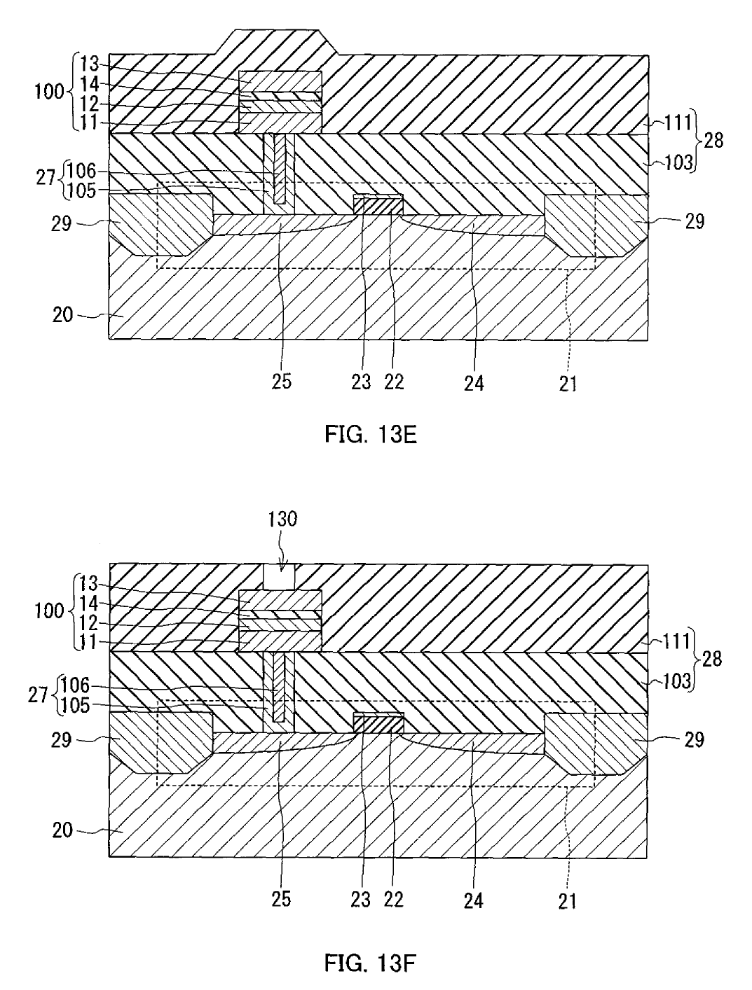

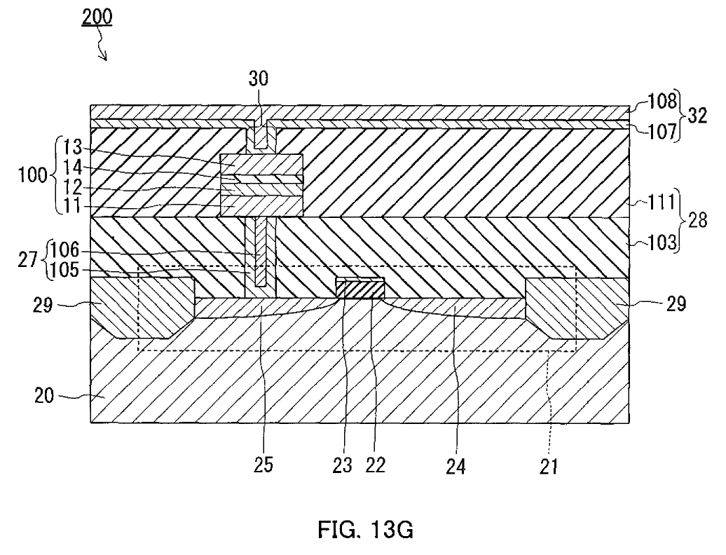

FIGS. 13A to 13G show an example of a method of manufacturing the electro-resistance element of the present invention and a memory including the same.

First, a step of FIG. 13A is carried out. Specifically, after forming a gate insulating film 22 and a gate electrode 23 on a substrate 20 made of a semiconductor, a pair of impurity diffusion layers (a source electrode 24 and a drain electrode 25) is formed at both ends of the gate electrode 23 on the substrate 20. In addition, an element isolating layer 29 is formed around a transistor 21. Next, a first protective insulation film 103, for example, made of an ozone TEOS (Tetra Ethyl Ortho Silicate) film is formed to cover the transistor 21 on the substrate 20. After that, a surface of the first protective insulation film 103 is planarized by CMP (Chemical Mechanical Polishing). Then, an opening 104 for a plug is formed by selectively etching through a part of the first protective insulation film 103 to expose one of the pair of the impurity diffusion layers.

Subsequently, a step of FIG. 13B is carried out. Specifically, a barrier metal 105 made of, for example, a titanium layer (a lower layer) and a titanium nitride layer (an upper layer) is formed on the first protective insulation film 103. After that, a plug metal 106 made of, for example, tungsten (W) or the like is deposited to fill in the opening 104. Then, the parts of the barrier metal 105 and the plug metal 106 exposing outside of the opening 104 are removed by CMP for forming a plug 27 shown in FIG. 13C. The plug metal part of the plug 27 electrically connects to the lower electrode 11.

Subsequently, as shown in FIG. 13C, a lower electrode layer 11a, a transition metal oxide layer (an electro-resistance layer) 12a, an insulating layer (a tunnel barrier layer) 14a and an upper electrode layer 13a are deposited on the first protective insulating film 103 in this order. The insulating layer 14a has a thickness in a range from 0.5 nm to 5 nm both inclusive.

Subsequently, patterning the lower electrode layer 11a, the transition metal oxide layer 12a, the insulating layer 14a and the upper electrode layer 13a forms a multilayer structure (an electro-resistance element 100) including the lower electrode 11, the electro-resistance layer 12, the tunnel barrier layer 14 and the upper electrode 13 as shown in FIG. 13D.

Subsequently, a second protective insulation film 111 made of, for example, an ozone TEOS film is formed to cover the multilayer structure on the first protective insulation film 103 as shown in FIG. 13E. The first protective insulation film 103 and the second protective insulation film 111 compose an interlayer insulating layer 28.

Subsequently, after planarizing the surface of the second protective insulation film 111 by CMP, a part of the second protective insulation film 111 was etched selectively for forming an opening 130 for a plug as shown in FIG. 13F. After that, an adhesive metal 107, for example made of a tantalum nitride film or the like, is formed on the second protective insulation film 111 as shown in FIG. 13G. Then, a wiring metal 108, for example made of tungsten, copper, aluminum or the like, is deposited to fill in the opening 130 for forming a plug 30. The adhesive metal 107 and the wiring metal 108 compose a bit line 32.

In the processes described above, some components (such as tungsten employed for the plug metal) are formed in the hydrogen-containing atmosphere. Therefore, components of the element are generally exposed to hydrogen in each plug forming step.

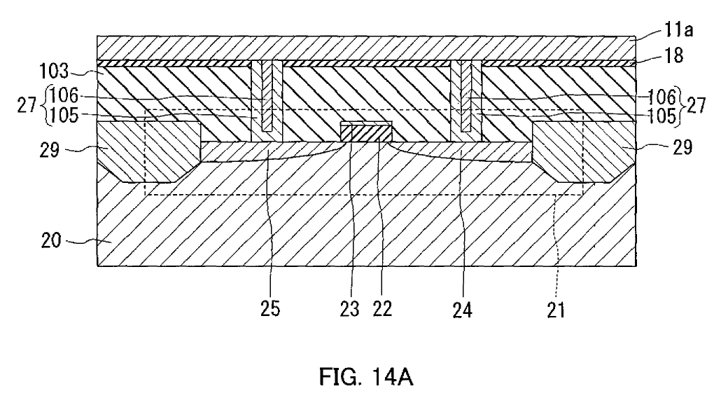

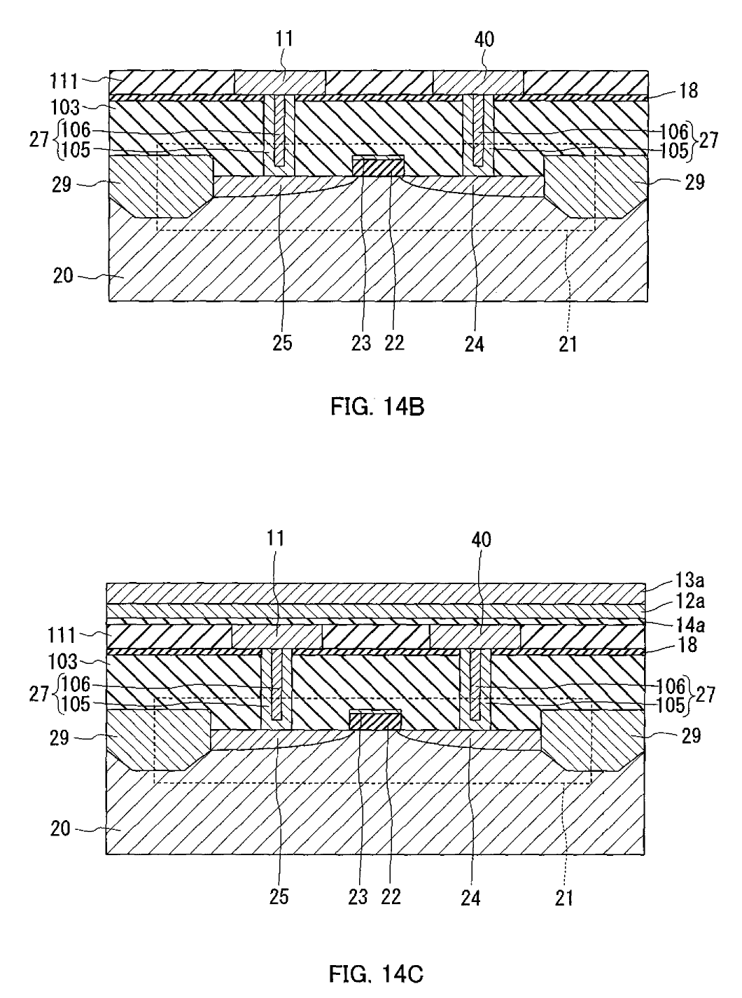

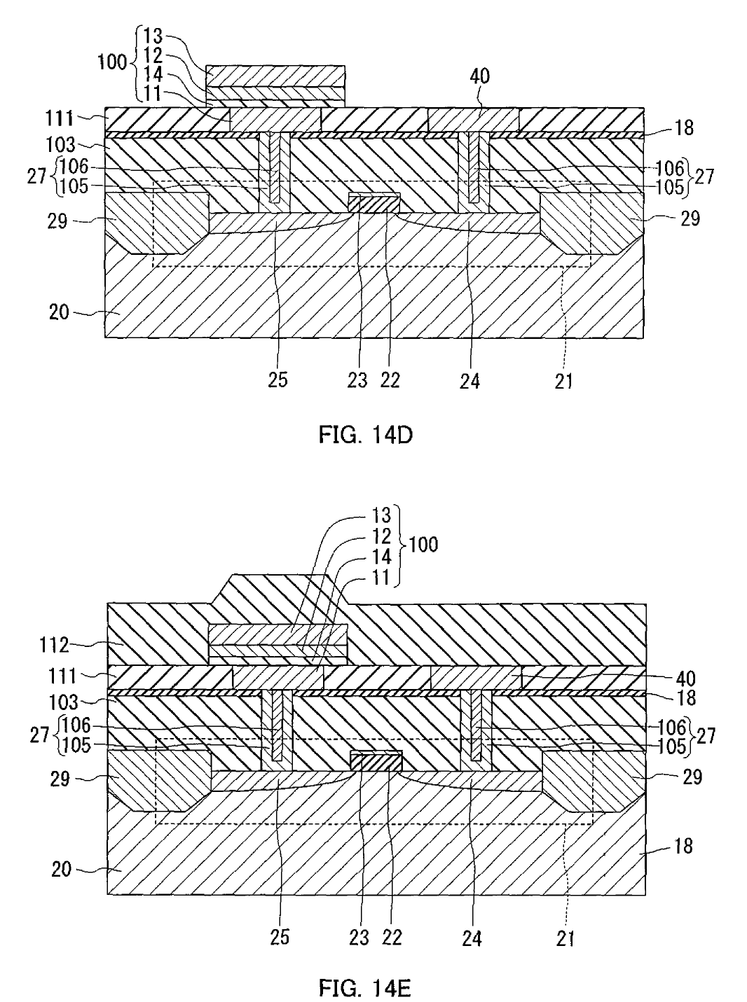

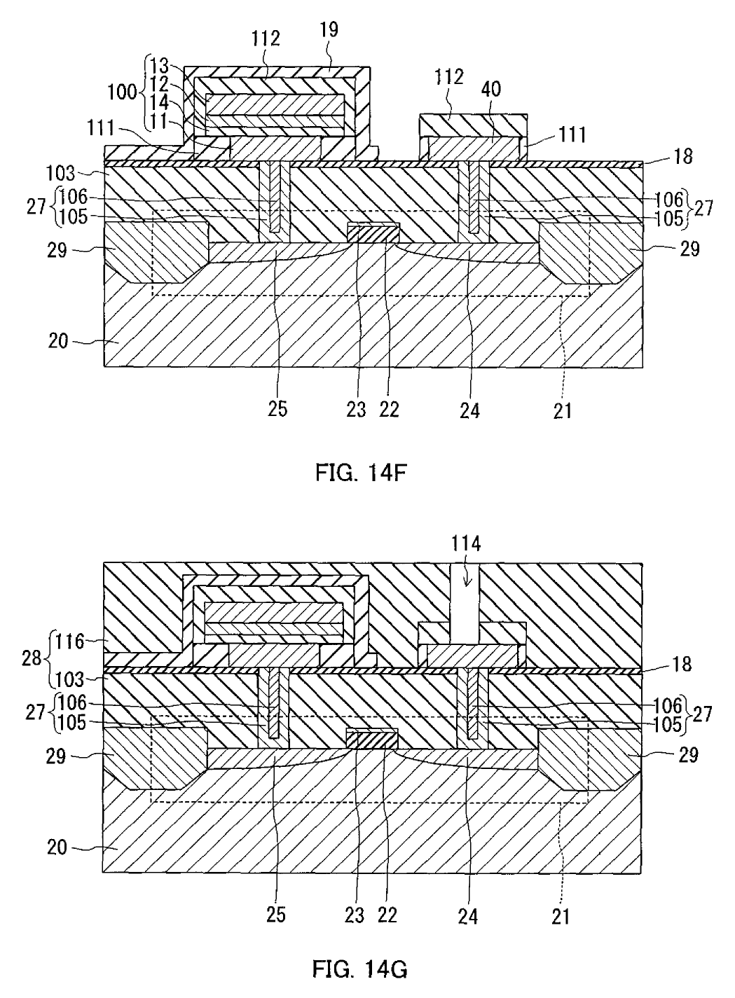

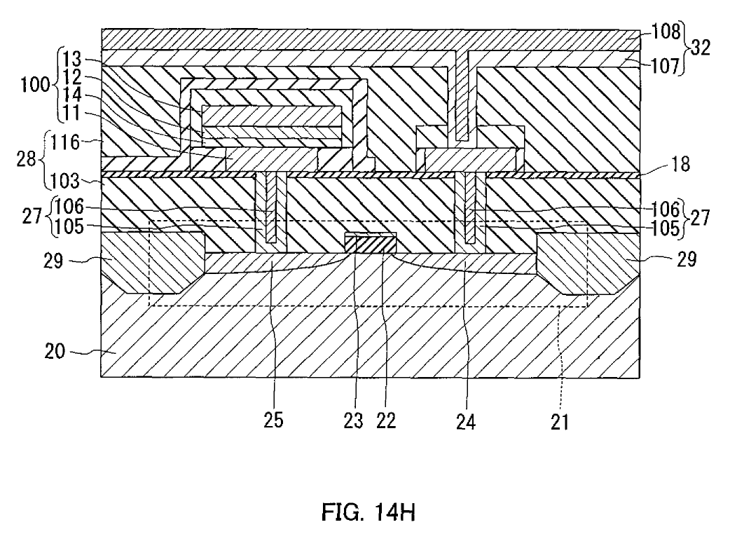

FIGS. 14A to 14G show another example of a method of manufacturing the electro-resistance element of the present invention and a memory including the same.

First, a step of FIG. 14A carries out the same steps shown in FIGS. 13A to 13B. It should be noted that the step of FIG. 14A forms a plug 27 connected to the source electrode 24 and another plug 27 connected to the drain electrode 25. In addition, a lower electrode layer 11a is deposited on the first protective insulating film 103. A hydrogen barrier layer 18 preferably is formed under the lower electrode layer 11a before forming the plugs. The hydrogen barrier layer 18 preferably employs SiN, TiAlO and the like.

Subsequently, patterning of the lower electrode layer 11a forms a lower electrode 11 connected to the drain electrode 25 via the plug 27 and an electrode 40 connected to the source electrode 24 via the plug 27 as shown in FIG. 14B. After that, a second protective insulating film 111 made of, for example, an ozone TEOS film is formed on them. Then, CMP planarizes a surface of the second protective insulating film 111 and exposes surfaces of the lower electrode 11 and the electrode 40.

Subsequently, an insulating layer (a tunnel barrier layer) 14a, a transition metal oxide layer (an electro-resistance layer) 12a and an upper electrode layer 13a are deposited on the second protective insulating film 111 as shown in FIG. 14C. The insulating layer 14a has a thickness in a range from 0.5 nm to 5 nm both inclusive.

Subsequently, patterning of the insulating layer 14a, the transition metal oxide layer 12a and the upper electrode layer 13a forms a multilayer structure (an electro-resistance element 100) including the lower electrode 11, the tunnel barrier layer 14, the electro-resistance layer 12 and the upper electrode 13 as shown in FIG. 14D. After that, a third protective insulating film 112 including, for example, an ozone TEOS film is formed on the second protective insulating film 111 to cover the electro-resistance element 100 as shown in FIG. 14E.

Subsequently, the third protective insulating film 112 and the second protective insulating film 111 are etched through the parts other than the vicinities of the electro-resistance element 100 and the electrode 40 as shown in FIG. 14F. After that, a hydrogen barrier layer 19 is deposited and then etched through the parts other than the vicinity of the electro-resistance element 100. In this way, the hydrogen barrier layers 18 and 19 surround the multilayer structure. The hydrogen barrier layer 19 preferably employs SiN, TiAlO, TiAlN and TiAlON.

Subsequently, a step of FIG. 14G is carries out. First, a fourth protective insulating film 116 is deposited, followed by CMP planarizing its surface. Next, a part of the fourth protective insulating film 116 was etched selectively to form an opening 114 for a plug getting through the electrode 40. The first protective insulating film 103 and the fourth protective insulating film 116 compose an interlayer insulating film 28.

Subsequently, an adhesive metal 107 is formed, made of a tantalum nitride film (Ta—N), nitrocarburized silicon (Si—C—N) or the like on the fourth protective insulating film 116 as shown in FIG. 14H. After that, a wiring metal 108 made of copper, aluminum or the like is deposited to fill in the opening 114. The adhesive metal 107 and the wiring metal 108 compose a bit line 32.

An electrode (not shown) passing through the hydrogen barrier layer 18 similar to the plugs 27 connects the upper electrode 13 to one of the electrodes disposed underneath, and another electrode (not shown) similar to the plugs 27 further connects it to an electrode wiring at the top surface. The lower electrode 11 preferably employs nitride such as a Ti—Al alloy and a stacked structure thereof both having high resistance to hydrogen exposure. The memory element fabricated by the process of FIGS. 14A to 14H exhibits a high passivation effect.

Each step shown in the processes of FIGS. 13A to 13G and 14A to 14H can be carried out by applying known techniques, such as those used for processes of manufacturing a semiconductor element, forming a thin film and microfabricating. Formation of each layer can employ various sputtering techniques, such as pulse laser deposition (PLD), ion beam deposition (IBD), cluster ion beam, RF, DC, electron cyclotron resonance (ECR), helicon, inductively coupled plasma (ICP), and facing target, molecular beam epitaxy (MBE) and ion plating, for example. It also may employ CVD (Chemical Vapor Deposition), MOCVD (Metalorganic Chemical Vapor Deposition), a plating method, MOD (Metalorganic Decomposition) or a sol-gel method, other than those PVD (Physical Vapor Deposition) techniques.

Microfabrication of each layer can employ methods used for processes of manufacturing a semiconductor element and a magnetic device (a magneto-resistive element such as GMR or TMR), for example. For example, physical or chemical etching such as ion milling, RIE (Reactive Ion Etching), and FIB (Focused Ion Beam) may be used. Photolithography techniques using a stepper for forming micro patterns, an EB (Electron Beam) technique and the like also may be combined for the use. The surfaces of the interlayer insulating layers and the conductors deposited in the contact holes can be planarized by, for example, CMP, cluster-ion beam etching, or the like.

Oxidization during manufacture of the electrodes and the electro-resistance layers is carried out under an appropriate atmosphere including, for example, atoms, molecules, ions, radicals and the like of oxygen. Such oxidization may vary in atmosphere, temperature, duration of time and reactivity. For example, when fabricating Ti—Al—O by sputtering, a Ti—Al—O film is formed in an argon atmosphere or an argon-oxygen mixture atmosphere and it may be followed by repeating a reaction in oxygen gas or O₂+inert gas. To generate plasma and radicals, known methods are applicable such as ECR discharge, glow discharge, RF discharge, helicon and ICP. Nitridation using nitrogen can be carried out by the same methods.

An electronic device including the electro-resistance element of the present invention can be formed by the methods described above or by combining them with other known methods.

### EXAMPLES

Hereinbelow, the present invention is described further in detail with reference to Examples. It should be noted that the present invention is not limited to the Examples described below.

### Example 1

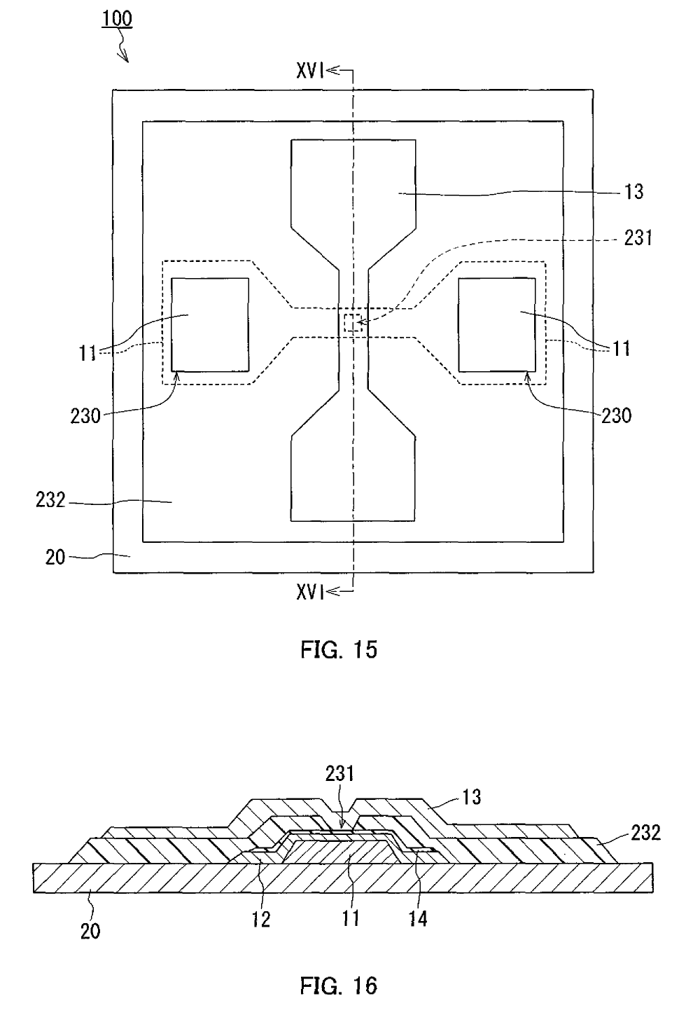

In Example 1, a sample (an electro-resistance element) including a multilayer structure shown in FIG. 1 and having a form shown in FIG. 15 was fabricated for evaluating its resistance change characteristic. Example 1 employed aluminum oxide (hereinafter, also referred to as “Al—O”) for a material of a tunnel barrier layer 14 and iron oxide (hereinafter, also referred to as “Fe—O”) for a material of an electro-resistance layer 12.

The sample shown in FIG. 15 was fabricated in the following manner. FIG. 16 shows a cross-sectional view taken along the line XVI-XVI of FIG. 15.

First, a Si substrate with a thermally oxidized film (a SiO₂ film) formed on its surface was prepared as a substrate 20. A lower electrode 11 having a predetermined shape was then formed on the substrate 20 using a metal mask. The lower electrode 11 was formed by stacking a TiAlN layer (200 nm in thickness) and a Pt layer (100 nm in thickness). The TiAlN layer was deposited by magnetron sputtering using a Ti₆₀Al₄₀ alloy target. The sputtering was carried out under a nitrogen-argon mixture atmosphere (volume ratio of nitrogen:argon was about 4:1) (pressure: 0.1 Pa) by holding the Si substrate at a temperature in the range from 0° C. to 400° C. (mainly at 350° C.) and applying electric power of DC 4 kW. The Pt layer was formed by magnetron sputtering. The sputtering was carried out under an argon atmosphere at a pressure of 0.7 Pa by setting the substrate temperature at 27° C. and applying electric power of 100 W. The TiAlN layer and the Pt layer were fabricated in the same vacuum chamber.

Next, an electro-resistance layer 12 (an Fe—O layer) and a tunnel barrier layer 14 (an Al—O layer) were stacked on a part of the lower electrode 11 using a metal mask having a square opening. The size of each formed electro-resistance layer 12 and tunnel barrier layer 14 was about 50 μm×50 μm corresponding to the opening of the metal mask. The metal mask was placed to match the center of its opening (where a center of a rectangular opening is defined as the point of intersection of two linear lines connecting the opposing vertexes) with the center of the lower electrode 11.

The Fe—O layer was formed by magnetron sputtering using FeO_{0.75} as a target. The sputtering was carried out under an argon-oxygen mixture atmosphere (volume ratio of argon:oxygen was about 8:1) (at a pressure of 0.6 Pa) by holding the Si substrate at a temperature in the range from room temperature to 400° C. (mainly at 300° C.) and applying electric power of RF 100 W. Evaluation of the fabricated layer by X-ray diffraction, infrared absorption and Raman spectroscopy showed that it was a γ-Fe₂O₃ layer.

The tunnel barrier layer made of Al₂O₃ (the Al—O layer) was fabricated by repeating a film formation of an Al layer with a thickness in a range from 0.2 nm to 0.7 nm and an oxidization of the Al layer. The Al layer was formed by magnetron sputtering using Al as a target. The sputtering was carried out under an argon atmosphere (at a pressure of 0.1 Pa) by setting the temperature of the Si substrate at room temperature and applying electric power of RF 100 W. The Al layer was oxidized in an atmosphere having an oxygen ratio of equal to or more than 99 volume % at a pressure of 100 Pa in a sealed container.

Employing the forming method repeating Al layer formation and oxidization of the layer enables forming a thin but highly insulating Al—O layer and reducing the time for fabricating an Al—O layer. Since oxygen diffusion into Al takes time, repeating the formation and the oxidization of a thin Al layer reduces the time for forming an entire tunnel barrier layer. The time reduction in Al—O layer formation is important to reduce the time for fabricating an electro-resistance element.

In the case of mass production, a plurality of wafers preferably are oxidized all together. For example, a large number of substrates, each having an Al layer formed, is placed in one chamber and oxidized all at one time to form an aluminum oxide layer on every substrate. Next, an Al layer is formed on the aluminum oxide layer of each substrate. After that, again, the large number of substrates is oxidized all together in one container to form an aluminum oxide layer on every substrate. Repeating such processes enables time reduction for processing in total. In this Example, the Al—O layer was fabricated by multi-step oxidization and collective wafer oxidization.

Subsequently, an interlayer insulating layer 232 was formed to cover the Fe—O and the Al—O layers. The interlayer insulating layer 232 employed an ozone TEOS layer (400 nm in thickness). After that, an opening 231 to form a Junction of the electro-resistance element and openings 230 to contact the lower electrode were formed by photolithography and dry etching. Then, a Pt layer (400 nm in thickness) was formed as an upper electrode 13 under the same condition as the lower electrode 11. Since the area of the opening 231 to form a junction makes an actual junction area, this area was varied in a range from 0.01 μm² to 25 μm² upon formation. Samples 1-1 to 1-11 were fabricated, each having 0.25 μm² of this area.

In this way, an electro-resistance element 100 having the major axis of the lower electrode 11 and that of the upper electrode 13 orthogonal to each other was fabricated as shown in FIGS. 15 and 16.

In this Example, a plurality of samples were fabricated by setting the thickness of the electro-resistance layer 12 (the Fe—O layer) as 50 nm and varying the thickness (x) of the tunnel barrier layer 14 (the Al—O layer). A voltage in a pulse form as shown in FIG. 7 was applied to each fabricated sample for evaluating each resistance change ratio.

The resistance change ratio was evaluated as follows. Using a pulse generator, a voltage of 1.5 V (positive bias voltage) as the RESET voltage, a voltage of −1.5 V (negative bias voltage) as the SET voltage and a voltage of 0.01 V (positive bias voltage) as the READ voltage, where each voltage is as shown in FIG. 7, were applied between the upper electrode 13 and the lower electrode 11 of each sample. The pulse width of each voltage was 150 ns (nanoseconds). The electric resistance value of each element was calculated from the output current value when applying the read voltage in each state after the set voltage application and after the reset voltage application.

Each resistance change ratio was obtained by the following formula, where R_{MAX} denotes the maximum value of the calculated electric resistance values and R_{MIN} does the minimum value thereof.

[Resistance Change Ratio]=(R_{MAX}−R_{MIN})/R_{MIN}

Results of the evaluation are shown in Table 1.

TABLE 1

| | | Thickness of each Step | |
|---|---|---|---|
| | Thickness of | in Multi-Step | Resistance |
| | Al—O Layer (x) | Oxidization (nm) | Change Ratio |
| Sample 1-1 | x = 0.3 nm | 0.3 | 4 |
| Sample 1-2 | x = 0.5 nm | 0.3/0.2 | 78 |
| Sample 1-3 | x = 0.7 nm | 0.3/0.4 | 380 |
| Sample 1-4 | x = 0.9 nm | 0.3/0.3/0.3 | 920 |
| Sample 1-5 | x = 1.2 nm | 0.3/0.3/0.3/0.3 | 590 |
| Sample 1-6 | x = 1.5 nm | 0.3/0.4/0.4/0.4 | 550 |
| Sample 1-7 | x = 2 nm | 0.3/0.4/0.7/0.6 | 320 |
| Sample 1-8 | x = 5 nm | 0.3/0.5/0.7 × 6 | 50 |
| Sample 1-9 | x = 10 nm | 0.3/0.6/0.7 × 13 | <1 |
| Sample 1-10 | x = 20 nm | 0.4/0.7 × 28 | <1 |
| Sample 1-11 | x = 50 nm | 0.3/0.7 × 71 | <1 |

“Thickness of each Step in Multi-Step Oxidization” in Table 1 is the estimated thickness of each Al—O layer based on the thickness of each formed Al layer. For example, an Al—O layer with a thickness of 0.3 nm and an Al—O layer with a thickness of 0.6 nm were formed, followed by repeating a formation of an Al—O layer with a thickness of 0.7 nm 13 times to fabricate the Sample 1-9.

As shown in Table 1, the resistance change ratios were large when the thicknesses of the Al—O layers (x) were equal to or lower than 5 nm. This means current flows via each Al—O layer, that is the Al—O layer successfully functions as a tunnel barrier layer. When the thickness (x) was equal to or more than 10 nm, it is considered that no current flowed via the Al—O layer and thus resistance change effects were not exhibited. In the case of 0.3 nm in the thickness (x), the resistance change ratio was not so large. This is considered to be because the tunnel barrier layer 14 was too thin to cover sufficiently. The samples having the thickness (x) in the range from 0.7 nm to 2 nm both inclusive showed equal to or more than 300 of resistance change ratio.

In addition, samples (the electro-resistance elements 100) having each junction area varied in a range from 0.01 μm² to 25 μm² were fabricated for the same evaluation. Although the resistance change ratios of the samples did not show much difference, the samples having smaller junction areas showed better characteristics. This is considered to be because a current concentration at the vicinity of the junction periphery causes easy leakage/short-circuit when the area is relatively large. Based on the obtained results, the junction area is considered preferably equal to or less than 0.25 μm² to obtain a stable and favorable characteristic.

Still in addition, Reference Samples A-1 to A-3 without a tunnel barrier layer 14 having the Fe—O layers varied in thickness were fabricated for evaluating the resistance change ratios. Results of the evaluation are shown in Table 2.

TABLE 2

| | Thickness of | Resistance |
|---|---|---|
| | Fe—O Layer (y) | Change Ratio |
| Sample A-1 | y = 5 nm | <1 |
| Sample A-2 | y = 30 nm | <1 |
| Sample A-3 | y = 50 nm | 7.5 |

As shown in Table 2, the resistance change characteristic was lost as the Fe—O layer became thinner. Not only is the resistance reduced as the Fe—O layer becomes thinner, but also a remarkable deterioration in characteristic is considered to be developed due to leakage/short-circuit when the Fe—O layer is equal to or less than 30 nm. This is supposedly caused both by the current flow increase due to the low resistance of the electro-resistance layer 12 and by the deterioration in film quality due to the extremely thin film.

Further in addition, write endurance of the Samples 1-1 and 1-6 and the Reference Sample A-3 was evaluated. Results are shown in Table 3.

TABLE 3

| | Applied Voltage/ | Write Endurance |
|---|---|---|
| | Duration of Time | (times) |
| Sample 1-1 | ±1.5 V/150 ns | 10 times or Less |
| Sample 1-6 | ±1.5 V/150 ns | 10⁴ times or More |
| Sample A-3 | ±1.5 V/150 ns | 10 times or Less |

The numbers in the column “write Endurance” in Table 3 mean how many pairs of a SET operation and a RESET operation were repeated until recording and reading information cannot be performed. The Sample 1-6 was remarkably excellent in write endurance compared to the Sample 1-1 and the Reference Sample A-3. It was found that the biggest current was flowing at each rising of the set voltage pulse application by measuring the amounts of current when applying the voltage pulses. The amount of current in the Sample 1-6 was about 0.5 mA at maximum, while that in the Sample 1-1 and the Reference Sample A-3 was as much as in the range from some mA to more than some tens of mA although such current flowed only for a moment. It is considered that the Sample 1-6 showed the small amount of maximum current because introduction of the tunnel barrier layer 14 with an adequate thickness reduced the amount of current upon recording and thus the element stress was reduced.

As described above, it was found that the preferable thickness of the tunnel barrier layer was in the range from 0.5 nm to 5 nm and that of the electro-resistance layer was equal to or less than 50 nm. When these conditions were satisfied, favorable resistance change characteristic was obtained.

Further, samples (the electro-resistance elements 100) with thickness of the Al—O layer defined as 1.2 nm and with thickness (y) of the Fe—O layer varied were fabricated for evaluation. Results of the evaluation are shown in Table 4.

TABLE 4

| | Thickness | Resistance | | Write |
|---|---|---|---|---|
| | of Fe—O | Change | Applied | Endurance |
| | Layer (y) | Ratio | Voltage/Time | (times) |
| Sample 1-12 | y = 5 nm | 11 | ±1.5 V/150 ns | 10² times or More |
| Sample 1-13 | y = 30 nm | 890 | ±1.5 V/150 ns | 10⁴ times or More |
| Sample 1-6 | y = 50 nm | 590 | ±1.5 V/150 ns | 10⁴ times or More |

In this evaluation result as well, a favorable resistance change characteristic was obtained when the tunnel barrier layer 14 was introduced and the thickness of the electro-resistance layer was equal to or less than 50 nm. The number of times for write endurance of the Sample 1-12 was 10² times or more, which was a favorable result. In addition, samples having Al—O layers thicker than 1.2 nm were evaluated as well. The samples showing more than several times of resistance change ratio and 10² times or more of write endurance had an Fe—O layer thickness in a range from 1 nm to 50 nm both inclusive.

### Example 2

In this Example, a memory element 200 including an electro-resistance element 100 as shown in FIG. 6 was fabricated for evaluating its resistance change characteristic. The tunnel barrier layer 14 employed an aluminum oxide layer (an Al—O layer) and the electro-resistance layer 12 employed an iron oxide layer (an Fe—O layer).

In the Example 2, the electro-resistance element 100 was formed on a substrate by a known method as shown in FIGS. 13A to 13G. The substrate employed a substrate having a first protective insulating film 103 and a MOS transistor formed thereon. The first protective insulating film 103 employed an ozone TEOS film planarized by CMP (400 nm in thickness).

A plug 27 formed on the first protective insulating film 103 was composed of a barrier metal 105 made of a titanium film and a titanium nitride film and a plug metal 106 made of tungsten.

A Ti—Al—N/Pt layer was deposited as a lower electrode layer 11a on that, followed by an Fe—O layer deposited as a transition metal oxide layer 12a, an Al—O layer deposited as an insulating layer 14a and a Pt layer deposited as an upper electrode layer 13a in this order.

The Ti—Al—N layer as the lower electrode layer 11a was formed by magnetron sputtering using a Ti₇₀Al₃₀ alloy target. The sputtering was carried out under a nitrogen-argon mixture atmosphere (mixture ratio at about 4:1) (at a pressure of 0.1 Pa) by setting a temperature of the Si substrate in a range from 0° C. to 400° C. (mainly at 350° C.) and applying electric power of DC 4 kW. The Pt layer was formed by magnetron sputtering in the same vacuum chamber as that where the Ti—Al—N layer was formed. The sputtering was carried out under an argon atmosphere at a pressure of 0.7 Pa with a substrate temperature at 27° C. and applied electric power of 100 W.

The Fe—O layer was formed in the same way as the Fe—O layer of the Example 1. As described in the Example 1, the formed Fe—O layer was a γ-Fe₂O₃ layer.

The Al—O layer, which is an Al₂O₃ layer, was formed by magnetron sputtering using Al as a target. The sputtering was carried out under an argon atmosphere at a pressure of 0.1 Pa by setting a temperature of the Si substrate at room temperature and applying electric power of RF 100 W. The Al—O layer was formed by repeating a formation of an Al layer with a thickness in a range from 0.3 nm to 0.7 nm and an oxidization of the Al layer in an oxygen containing atmosphere.

The Pt layer as the upper electrode layer 13a was fabricated by magnetron sputtering under an argon atmosphere at a pressure of 0.7 Pa with a substrate temperature at 27° C. and applied electric power of 100 W.

Subsequently, a multilayer structure (the electro-resistance element 100) including a lower electrode 11, an electro-resistance layer 12, a tunnel barrier layer 14 and an upper electrode 13 was formed by patterning the lower electrode layer 11a, the transition metal oxide layer 12a, the insulating layer 14a and the upper electrode layer 13a as shown in FIG. 13D. After that, a second protective insulating film 111 (800 nm in thickness) made of an ozone TEOS film was formed on the first protective insulating film 103 to cover the electro-resistance element 100 as shown in FIG. 13E.

Subsequently, the second protective insulating film 111 was planarized by CMP and an opening 130 for a plug was formed on the second protective insulating film 111 as shown in FIG. 13F. After that, an adhesive metal 107 (10 nm in thickness) made of tantalum nitride (Ta—N) and a wiring metal 108 (300 nm in thickness) made of copper (Cu) were disposed to fill in the plug 130, and they were patterned to configure a bit line 32 as shown in FIG. 13G. Lastly, it was sintered (thermally treated) at a temperature of 400° C. for ten minutes in a nitrogen gas. Each sample of the Example 2 (the memory element 200) was fabricated in this way.

Pulsed voltages were applied to the fabricated memory element as illustrated with reference to FIG. 7 for evaluating the resistance change characteristic of the memory element 200. Evaluation was made by turning ON the transistor by voltage application to the gate electrode 23, applying a voltage between the source electrode 24 and the upper electrode 13 and measuring the current value output from the element. Here, the voltages shown in FIG. 7 were defined as follows: the reset voltage was at a voltage of 2.2 V (positive bias voltage), the set voltage was at a voltage of −2.3 V (negative bias voltage) and the read voltage was at a voltage of 0.05 V (positive bias voltage). The pulse width of each voltage was 200 ns. The resistance value of the element was calculated based on difference values between a reference current value and the output current value of the element. The reference current value was obtained by applying the same voltage as the read voltage applied to the element to a reference resistance disposed separately from the object element.

Results of the evaluation are shown in Table 5. Table 5 also shows the thickness of the Fe—O layer and the junction area of each sample.

TABLE 5

| | Thickness | | Resistance | |
|---|---|---|---|---|
| | of Fe—O | Junction | Change | Write Endurance |
| | Layer (y) | Area | Ratio | (times) |
| Sample 2-1 | y = 10 nm | 0.005 μm² | 20 | 10⁴ times or More |
| Sample 2-2 | y = 30 nm | 0.01 μm² | 35 | 10⁴ times or More |
| Sample 2-3 | y = 50 nm | 0.01 μm² | 55 | 10⁴ times or More |

As shown in Table 5, the Samples 2-1 to 2-3 did not lose their memory function even when subjected to 104 times or more of the set and the reset voltages. It is considered that the Samples 2-1 to 2-3 showed relatively small resistance change ratios due to the influence of contact resistance such as wirings.

Subsequently, the Sample 2-1 was aligned in a matrix (four by four) to construct a 16-bit memory 300 and to check the operation as a memory array. The result showed that it was functioning successfully as a random access electro-resistance memory.

### Example 3

In the Example 3, a memory element as shown in FIG. 14H was fabricated for evaluating its resistance change characteristic. In this Example, the tunnel barrier layer 14 employed a silicon oxide layer (a Si—O layer) and the electro-resistance layer 12 employed an iron oxide layer (an Fe—O layer).

In the Example 3, the electro-resistance element 100 and a memory element were formed on a substrate by a known method as shown in FIGS. 14A to 14H. The substrate employed a substrate having a first protective insulating film 103 and a MOS transistor formed thereon. The first protective insulating film 103 employed an ozone TEOS film planarized by CMP (400 nm in thickness).

First, a lower electrode layer 11a was deposited on the first protective insulating film 103 as shown in FIG. 14A. The hydrogen barrier layer 18 under the lower electrode layer 11a employed a SiN layer (200 nm in thickness). Next, the lower electrode layer 11a was patterned to form a second protective insulating film 111 made of an ozone TEOS film on it, followed by planarization of the second protective insulating film 111 by CMP as shown in FIG. 14B. The CMP was stopped when the second protective insulating film 111 was remaining about 50 nm on the lower electrode 11, and the second protective insulating film 111 was dry etched until the surfaces of the lower electrode 11 and the electrode 40 were exposed. The lower electrode layer 11a employed Ti—Al—N (250 nm in thickness)/Pt (50 nm in thickness).

The Ti—Al—N layer was formed by magnetron sputtering using a Ti₇₀Al₃₀ alloy target. The sputtering was carried out under a nitrogen-argon mixture atmosphere (mixture ratio at about 4:1) (at a pressure of 0.1 Pa) by setting a temperature of the Si substrate in a range from 0° C. to 400° C. (mainly at 350° C.) and applying electric power of DC 4 kW. The Pt layer was formed by magnetron sputtering in the same vacuum chamber as that where the Ti—Al—N layer was formed. The sputtering was carried out under an argon atmosphere at a pressure of 0.7 Pa with a substrate temperature at 27° C. and applied electric power of 100 W.

Subsequently, an insulating layer 14a to be a tunnel barrier layer, a transition metal oxide layer 12a to be an electro-resistance layer and an upper electrode layer 13a were formed on the second protective insulating film 111 and the lower electrode 11 as shown in FIG. 14C. The insulating layer 14a employed a Si—O layer (4 nm in thickness), the transition metal oxide layer 12a employed an Fe—O layer (from 1 nm to 50 nm in thickness: typically 20 nm) and the upper electrode layer 13a employed a Pt layer (100 nm in thickness).

The Fe—O layer, which is the transition metal oxide layer 12a, was formed by magnetron sputtering using FeO_{0.75} as a target. The sputtering was carried out under an argon atmosphere (at a pressure of 0.6 Pa) by holding the Si substrate at a temperature in the range from room temperature to 400° C. (mainly at 300° C.) and applying electric power of RF 100 W. The fabricated layer was identified as an Fe₃O₄ layer by resistivity measurement, magnetic measurement, X-ray diffraction, infrared absorption and Raman spectroscopy.

The Si—O layer (a SiO₂ layer) was formed by magnetron sputtering using SiO₂ as a target. The sputtering was carried out under an argon-oxygen mixture atmosphere (argon:oxygen was 4:1) (at a pressure of 0.6 Pa) by setting the temperature of the Si substrate in a range from room temperature to 300° C. (typically at 150° C.) and applying electric power of RF 150 W. The Pt layer for the upper electrode layer 13a was formed by magnetron sputtering under an argon atmosphere (at a pressure of 0.7 Pa) at a substrate temperature of 27° C. and applied electric power of 100 W.

Subsequently, a multilayer structure (an electro-resistance element 100) including a tunnel barrier layer 14, an electro-resistance layer 12 and an upper electrode 13 was formed by patterning the insulating layer 14a, the transition metal oxide layer 12a and the upper electrode layer 13a as shown in FIG. 14D. After that, a third protective insulating film 112 (800 nm in thickness) made of an ozone TEOS film was formed on the second protective insulating film 111 to cover the electro-resistance element 100 as shown in FIG. 14E. Then, the third protective insulating film 112 was etched in a form to cover the multilayer structure, and a Ti₅₀Al₅₀O layer, which is a hydrogen barrier layer 19, was formed thereon. In this way, a structure as shown in FIG. 14F was formed.

Subsequently, an ozone TEOS film was formed as a fourth protective insulating film 116 and its surface was planarized by CMP as shown in FIG. 14G. After that, an opening 114 getting through the electrode 40 was formed by selectively etching a part of the fourth protective insulating film 116. Then, an adhesive metal 107 made of Ta—N and a wiring metal 108 made of Al were deposited on the fourth protective insulating film 116 to fill in the opening 114 for composition of a bit line 32 as shown in FIG. 14H. In this way, each memory element was fabricated.

Similar to the Example 2, pulsed voltages were applied to the fabricated memory elements (Samples 3-1 to 3-3) and their current values were measured for evaluating the resistance change characteristic of the samples. It should be noted that the reset voltage was defined as a voltage of 2.5 V (positive bias voltage), the set voltage as a voltage of −2.5 V (negative bias voltage) and the read voltage as a voltage of 0.05 V (positive bias voltage) in the Example 3. In addition, the pulse width of each voltage was 250 ns.

Results of the evaluation, thickness (y) of Fe—O layers and junction areas are shown in Table 6.

TABLE 6

| | Thickness | | Resistance | |
|---|---|---|---|---|
| | of Fe—O | Junction | Change | Write Endurance |
| | Layer (y) | Area | Ratio | (times) |
| Sample 3-1 | y = 10 nm | 0.005 μm² | 10 | 10⁴ times or More |
| Sample 3-2 | y = 20 nm | 0.01 μm² | 10 | 10⁴ times or More |
| Sample 3-3 | y = 50 nm | 0.01 μm² | 20 | 10⁴ times or More |

The resistance change ratios of the Samples 3-1 to 3-3 were equal to or more than 10, which means they were operated stably as memory elements. In addition, these samples did not lose their memory functions even when subjected to 10⁴ times or more of the set and the reset voltages.

Still in addition, the samples were evaluated similarly by replacing the rectangular waveform driving pulse with trapezoidal or sine wave. The trapezoidal pulse was shaped with a slope of about 10 ns in each rising and falling edge of the rectangular pulse. The pulse width here was 200 ns. The evaluation showed that memory elements operated stably even when changed the waveform of driving pulse. It was also found that the oscillating ringing noise, which used to arise at the rising and falling of the output signals when applying the rectangular pulse, was remarkably reduced by using the trapezoidal or sine wave pulse.

Subsequently, the Sample 3-2 was aligned in a matrix (four by four) to construct a 16-bit memory 300 (a memory array) and to check the operation as a memory array. The result showed that the memory successfully operated as a random access electro-resistance memory.

### Example 4

In the Example 4, an electro-resistance element 100 as shown in FIG. 1 was fabricated in a shape shown in FIG. 15 for evaluating its resistance change characteristic. In the Example 4, the tunnel barrier layer 14 employed a magnesium oxide layer (an MgO layer), a titanium oxide layer (a TiO₂ layer) or a tantalum oxide layer (a TaO₂ layer). The electro-resistance layer 12 employed an iron oxide layer (an Fe—O layer, 10 nm in thickness).

The samples for the Example 4 were fabricated under the same condition as the samples for the Example 1 other than using an iron oxide layer with a thickness of 10 nm and using an MgO layer (1.5 nm in thickness), a TiO₂ layer (1.5 nm in thickness) or TaO₂ layer (1.5 nm in thickness) instead of the Al—O layer.

The MgO layer was fabricated by magnetron sputtering using MgO as a target. The sputtering was carried out under an argon-oxygen mixture atmosphere (a typical mixture ratio was 1:2) (at a pressure of 5 Pa) by setting the temperature of the Si substrate in a range from 300° C. to 700° C. and applying electric power of RF 100 W. When a sample using titanium oxide (TiO₂) or tantalum oxide (TaO₂) as material for the tunnel barrier layer, a titanium oxide layer or a tantalum oxide layer was formed under the same condition as the MgO layer.

Similar to the Example 1, pulsed voltages were applied to each fabricated sample as shown in FIG. 7 and their current values were measured for evaluating their resistance change characteristic. It should be noted that the reset voltage was defined as a voltage of 3.5 V (positive bias voltage), the set voltage as a voltage of −3.5 V (negative bias voltage) and the read voltage as a voltage of 0.01 V (positive bias voltage) in the Example 4. In addition, the pulse width of each voltage was 250 ns. Results of the evaluation, material and thickness of tunnel barrier layers and junction areas are shown in Table 7.

TABLE 7

| | | | Resistance | |
|---|---|---|---|---|
| | Tunnel Barrier | Junction | Change | Write Endurance |
| | Layer 14 | Area | Ratio | (times) |
| Sample 4-1 | MgO (15 nm | 0.25 μm² | 10 | 10⁴ times or More |
| | in Thickness) | | | |
| Sample 4-2 | TiO₂ (1.5 nm | 0.25 μm² | 10 | 10⁴ times or More |
| | in Thickness) | | | |
| Sample 4-3 | TaO₂ (1.5 nm | 0.25 μm² | 10 | 10⁴ times or More |
| | in Thickness) | | | |

### Example 5

In the Example 5, an electro-resistance element 100 as shown in FIG. 1 was fabricated in a shape as shown in FIG. 15 for evaluating its resistance change characteristic. In the Example 5, the tunnel barrier layer 14 employed an aluminum oxide layer (an Al—O layer) having a thickness of 1.5 nm. The electro-resistance layer 12 employed an iron oxide layer (an Fe—O layer) having a thickness of 10 nm.

The sample for the Example 5 was fabricated under the same condition as the samples for the Example 1 other than the thickness of iron oxide layer and the conditions of forming the tunnel barrier layer 14 (the Al—O layer).

The tunnel barrier layer 14 (the Al—O layer: an Al₂O₃ layer) in the Example 5 was formed by multi-step oxidization, in which formation and oxidization of an Al layer are repeated. The Al layers were formed by magnetron sputtering using Al as a target. The sputtering was carried out under an argon atmosphere at a pressure of 0.1 Pa by setting the temperature of the temperature of the Si substrate at room temperature and applying electric power of RF 100 W. Thickness of Al—O layer at each stage was 0.3 nm, 0.4 nm, 0.4 nm and 0.4 nm.

Voltages in a pulse form were applied to the fabricated sample (junction area: 0.25 μm²) as shown in FIG. 8 between the upper and the lower electrodes for evaluating its resistance change characteristic. Here, the voltages shown in FIG. 8 were defined as follows: the reset voltage was at a voltage of 1.5 V (positive bias voltage, with a pulse width of 500 ns), the set voltage was at a voltage of 3.5 V (positive bias voltage, with a pulse width of 200 ns) and the read voltage was at a voltage of 0.01 V (positive bias voltage, with a pulse width of 200 ns). The electric resistance values of the element were calculated from the output current values when applying the read voltage in each state after applying the set voltage and the reset voltage. The resistance change ratio of the element was obtained based on the calculated electric resistance value. Results of the evaluation are shown in Table 8.

TABLE 8

| | Resistance Change | Write Endurance |
|---|---|---|
| | Ratio | (times) |
| Sample 5-1 | 400 | 10⁴ times or More |

### Example 6

In the Example 6, an electro-resistance element 100 as shown in FIG. 1 was fabricated in a shape shown in FIG. 15 for evaluating its resistance change characteristic. In the Example 6, the tunnel barrier layer 14 employed a silicon nitride layer (a Si—N layer) and the electro-resistance layer 12 employed an iron oxide layer (an Fe—O layer: 50 nm in thickness).

The sample for the Example 6 were fabricated under the same condition as the samples for the Example 1 other than using a Si—N layer (1.5 nm in thickness) instead of the Al—O layer. The Si—N layer was formed by plasma CVD setting a substrate temperature in a range from 300° C. to 800° C. (typically at 350° C.).

Similar to the Example 1, pulsed voltages were applied to the fabricated sample as shown in FIG. 7 and its current values were measured for evaluating its resistance change characteristic. It should be noted that the reset voltage was defined as a voltage of 1.5 V (positive bias voltage), the set voltage as a voltage of −1.5 V (negative bias voltage) and the read voltage as a voltage of 0.01 V (positive bias voltage) in the Example 6. The pulse width of each voltage was 150 ns. Results of the evaluation, material and thickness of the tunnel barrier layer and the junction area are shown in Table 9.

TABLE 9

| | | | Resistance | |
|---|---|---|---|---|
| | Tunnel Barrier | Junction | Change | Write Endurance |
| | Layer14 | Area | Ratio | (times) |
| Sample 6-1 | SiN (1.5 nm in | 0.25 μm² | 10 | 10⁴ times of More |
| | Thickness) | | | |

As shown in each Example above, the electro-resistance element of the present invention including a tunnel barrier layer shows a favorable resistance change characteristic even when reducing the film thickness. Thus, the electro-resistance element of the present invention can be applied to highly integrated memories requiring miniaturization of elements.

The present invention is applicable to an electro-resistance element and an electronic device including the same. The electro-resistance element can be miniaturized and applicable to various electronic devices. Examples of electronic devices using the electro-resistance element of the present invention may be non-volatile memories, switching elements, sensors and image displaying devices, which may be used for information communication terminals.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An electro-resistance element comprising a first electrode, a second electrode, and an electro-resistance layer and an insulating layer stacked between the first and the second electrodes,
the insulating layer having a thickness in a range from 0.5 nm to 5 nm both inclusive,
the electro-resistance layer being a layer having a plurality of states in which electric resistance values are different and being switchable between the states by applying a voltage or a current between the first and the second electrodes, and
the electro-resistance layer containing transition metal oxide as its main component.

2. The electro-resistance element according to claim 1, wherein the insulating layer is disposed between the electro-resistance layer and the first electrode or between the electro-resistance layer and the second electrode.

3. The electro-resistance element according to claim 1, wherein the electro-resistance layer has a thickness in a range from 1 nm to 500 nm both inclusive.

4. The electro-resistance element according to claim 1, wherein the electro-resistance layer has a thickness of more than 5 nm.

5. The electro-resistance element according to claim 1, wherein the transition metal oxide is iron oxide.

6. An electro-resistance memory comprising the electro-resistance element according to claim 1 as a memory element.

7. The electro-resistance memory according to claim 6 comprising a plurality of the electro-resistance elements aligned in a matrix.

8. The electro-resistance memory according to claim 6 further comprising a switching element connected to the electro-resistance element.

9. A method of manufacturing an electro-resistance element, the element including an electro-resistance layer having a plurality of states in which electric resistance values are different and being switchable between the states by applying a voltage or a current, the method comprising:
(i) forming a first electrode;
(ii) forming a stacked structure including an insulating layer and the electro-resistance layer on the first electrode; and
(iii) forming a second electrode on the stacked structure,
wherein the insulating layer has a thickness in a range from 0.5 nm to 5 nm both inclusive, and
the electro-resistance layer contains transition metal oxide as its main component.

10. The manufacturing method according to claim 9, wherein the stacked structure comprises the insulating layer formed on the first electrode and the electro-resistance layer formed on the insulating layer.

11. The manufacturing method according to claim 9, wherein the stacked structure comprises the electro-resistance layer formed on the first electrode and the insulating layer formed on the electro-resistance layer.

12. The manufacturing method according to claim 9, wherein in the step (ii) the insulating layer is formed by repeating a film forming step and an oxidizing step a plurality of times,
the film forming step forming a precursor film including an element constituting the insulating layer, and
the oxidizing step oxidizing the precursor film under an oxidizing atmosphere.

13. The manufacturing method according to claim 12, wherein a plurality of substrates having the precursor film formed thereon are oxidized all together under the oxidizing atmosphere in the oxidizing step.

14. The manufacturing method according to claim 12, wherein the oxidizing atmosphere is at least one atmosphere selected from oxygen gas atmosphere, oxygen plasma atmosphere and ozone atmosphere.

15. The manufacturing method according to claim 9, wherein the transition metal oxide is iron oxide.

16. The manufacturing method according to claim 9, wherein the electro-resistance layer has a thickness of more than 5 nm.
